(19) United States
(12) Patent Application Publication
(10) Pub. No.: US 2011/0241185 A1
(43) Pub. Date: Oct. 6, 2011

(54) SIGNAL SHIELDING THROUGH-SUBSTRATE VIAS FOR 3D INTEGRATION

(75) Inventors: Steven J. Koester, Ossining, NY (US); Fei Liu, Mt. Kisco, NY (US)

(73) Assignee: INTERNATIONAL BUSINESS MACHINES CORPORATION, Armonk, NY (US)

(21) Appl. No.: 12/754,108

(22) Filed: Apr. 5, 2010

(51) Int. Cl. H01L 23/538; H01L 21/768

(52) U.S. Cl. 257/659; 438/667; 257/E23.174; 257/E21.597

(57) ABSTRACT

A shielded through-substrate via (TSV) structure includes a first through-substrate via configured to transmit a signal at least from a top surface of a semiconductor device layer in a substrate to a bottommost surface of the substrate. The shielded TSV structure includes at least one second TSV located on the outside of the first TSV and configured to laterally shield the first TSV from external electrical signals. The at least one second TSV can be a unitary cylindrical structure including the first TSV therein, or a plurality of discrete structures configured to laterally shield the first TSV with gaps thereamongst. The at least one second TSV can include a conductive material that is different from the material of the substrate, or the at least one TSV can include a doped semiconductor material that is derived from the semiconductor material within the substrate.

### BACKGROUND

The present invention relates to semiconductor structures including a shielded through-substrate via structure and methods of manufacturing the same.

Chip stacking refers to a method of assembling two or more semiconductor chips so that the semiconductor chips that are placed in physical proximity to one another are also electrically connected among one another. Chip stacking is typically performed vertically, i.e., one chip is placed above or below another chip. When two chips are brought together vertically, a set of conductive contact structures on the top surface of an underlying chip is aligned to another set of conductive contact structures on the bottom surface of an overlying chip. The conductive structures may be formed on the side of metal interconnect structures, or they may be formed on the side of a substrate on which semiconductor devices are formed.

3D integration may be performed between a pair of substrates, a substrate and a set of chips, or between multiple pairs of chips. 3D integration provides vertical signal paths between stacked chips, providing a wide bandwidth for transmitting and receiving electrical signals between stacked chips. The vertical signal paths are enabled by through-substrate vias (TSVs), which are vias extending at least from a topmost surface of a semiconductor device layer in a substrate to a backside surface of the substrate. 3D integration effectively reduces the lengths of signal paths and allows faster transmission of electrical signals between various device components located in various portions of stacked semiconductor chips.

One of the limitations to the benefits of 3D integration is imposed by cross-talk between signals in TSVs. Cross-talk between TSVs can degrade the overall system level performance of a stacked structure of multiple semiconductor chips by introducing noise into signals through TSVs, which can cause false transient signals and limit the maximum frequency of signals that can be transmitted through the TSVs.

### BRIEF SUMMARY

A semiconductor structure including a shielded through-substrate via (TSV) structure is provided. The shielded TSV structure includes a first through-substrate via configured to transmit a signal at least from a top surface of a semiconductor device layer in a substrate to a bottommost surface of the substrate. The shielded TSV structure includes at least one second TSV located on the outside of the first TSV and configured to laterally shield the first TSV from external electrical signals. The at least one second TSV can be a unitary cylindrical structure including the first TSV therein, or a plurality of discrete structures configured to laterally shield the first TSV with gaps thereamongst. The at least one second TSV can include a conductive material that is different from the material of the substrate, or the at least one TSV can include a doped semiconductor material that is derived from the semiconductor material within the substrate. The at least one second TSV can extend fully or partially through the substrate in a vertical direction.

According to an aspect of the present invention, a semiconductor structure is provided, which includes a substrate and at least one shielded through-substrate via (TSV) structure embedded in the substrate. The substrate includes a semiconductor layer and an interconnect dielectric layer. At least one semiconductor device is located at an interface between the semiconductor layer and the interconnect dielectric layer. Each of the at least one shielded TSV structure includes a first TSV structure and at least one second TSV structure. The first TSV structure includes a first conductive material, is electrically insulated from the substrate, and extends at least from the interface to a back side surface of the substrate. The at least one second TSV structure includes a second conductive material, extends from the back side surface of the substrate into the substrate, and is configured to shield electrical signals within the first TSV structure from external electromagnetic signals.

According to another aspect of the present invention, a method of forming a semiconductor structure is provided, which includes: forming a plurality of trenches extending from a front side surface of a substrate into the substrate; forming a dielectric liner in each of the plurality of trenches; filling the plurality of trenches with a conductive material; and recessing a back side surface of the substrate, whereby remaining portions of the conductive material in the plurality of trenches constitute at least one shielded through-substrate via (TSV) structure embedded in the substrate, wherein each of the at least one shielded TSV structure includes a first TSV structure and at least one second TSV structure, the first TSV structure and the at least one second TSV structure are electrically isolated from the substrate, and the at least one second TSV structure is configured to shield electrical signals within the first TSV structure from external electromagnetic signals.

According to yet another aspect of the present invention, another method of forming a semiconductor structure is provided, which includes forming a trench extending from a front side surface of a substrate into the substrate; doping a semiconductor material portion around the trench to form a doped semiconductor material portion by introducing dopants through sidewalls of the trench into the substrate; forming a dielectric liner on sidewalls of the doped semiconductor material portion; filling the trench with a conductive material; and recessing a back side surface of the substrate, whereby a remaining portion of the conductive material in the trench constitutes a first through-substrate via (TSV) structure and a remaining portion of the doped semiconductor material portion constitutes a second TSV structure, and the first TSV structure and the second TSV structure have end surfaces that are coplanar with the back side surface after the recessing.

### BRIEF DESCRIPTION OF THE SEVERAL VIEWS OF THE DRAWINGS

FIGS. 1-3 and 5-9 are sequential vertical cross-sectional views of a first exemplary semiconductor structure at various stages of a manufacturing process according to a first embodiment of the present invention.

FIG. 4A is a horizontal cross-sectional view of the first exemplary semiconductor structure along the plane X-X′ in FIG. 3 according to the first embodiment of the present invention.

FIG. 4B is a horizontal cross-sectional view of a first variation of the first exemplary semiconductor structure along a plane equivalent to the plane X-X′ in FIG. 3 according to the first embodiment of the present invention.

FIG. 4C is a horizontal cross-sectional view of a second variation of the first exemplary semiconductor structure along a plane equivalent to the plane X-X′ in FIG. 3 according to the first embodiment of the present invention.

FIG. 4D is a horizontal cross-sectional view of a third variation of the first exemplary semiconductor structure along a plane equivalent to the plane X-X′ in FIG. 3 according to the first embodiment of the present invention.

FIGS. 10-12 are sequential vertical cross-sectional views of a second exemplary semiconductor structure at various stages of a manufacturing process according to a second embodiment of the present invention.

FIGS. 13-22 are sequential vertical cross-sectional views of a third exemplary semiconductor structure at various stages of a manufacturing process according to a third embodiment of the present invention.

FIG. 23 is a vertical cross-sectional view of a variation of the third exemplary semiconductor structure according to the third embodiment of the present invention.

FIGS. 24-27 are sequential vertical cross-sectional views of a fourth exemplary semiconductor structure at various stages of a manufacturing process according to a fourth embodiment of the present invention.

FIG. 28 is a vertical cross-sectional view of a variation of the fourth exemplary semiconductor structure according to the fourth embodiment of the present invention.

### DETAILED DESCRIPTION

As stated above, the present invention relates to semiconductor structures including a shielded through-substrate via structure and methods of manufacturing the same, which are now described in detail with accompanying figures. Throughout the drawings, the same reference numerals or letters are used to designate like or equivalent elements. The drawings are not necessarily drawn to scale.

As used herein, a “semiconductor chip” is a structure including at least one of an integrated circuit, a passive component such as a capacitor, a resistor, an inductor, or a diode, or a micro-mechanical-electrical structure (MEMS), or a combination thereof that may be formed on a substrate including a semiconductor material.

As used herein, an element is “electrically connected” to another element if there exists an electrically conductive path between said element and said other element.

As used herein, an element is “electrically insulated” from another element if there is no electrically conductive path between said element and said other element.

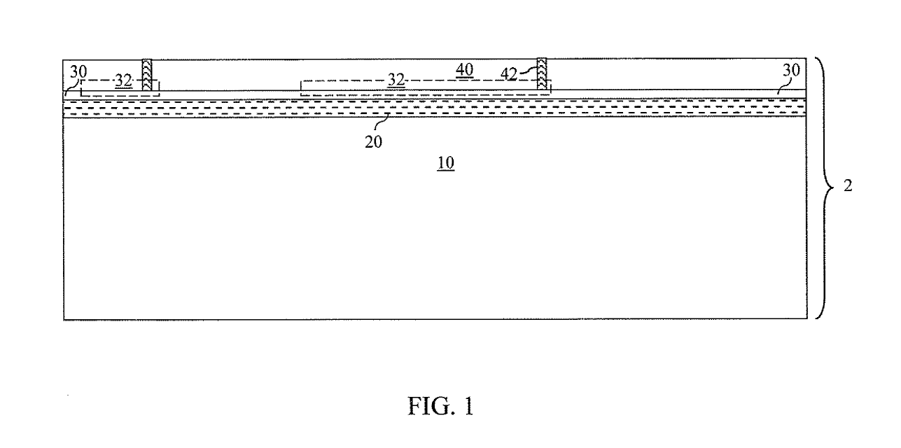

Referring to FIG. 1, a first exemplary semiconductor structure according to a first embodiment of the present invention includes a first substrate 2. The first substrate 2 can include a semiconductor-on-insulator (SOI) substrate, a bulk semiconductor substrate, or a hybrid substrate including at least one SOI portion and at least one bulk portion. If the first substrate 2 includes an SOI substrate, the SOI substrate can contain, from bottom to top, a first handle substrate 10, a first buried insulator layer 20, and a first top semiconductor layer 30. Typical materials employed for the first handle substrate 10 include a semiconductor material or silicate glass.

The first handle substrate 10 can include a semiconductor material, a dielectric material, a conductive material, or a combination thereof. Typically, the first handle substrate 20 includes a semiconductor material. The thickness of the handle substrate 10 can be from 100 microns to 1,000 microns, although lesser and greater thicknesses can also be employed. The first buried insulator layer 20 includes a dielectric material such as silicon oxide, silicon nitride, and/or silicon oxynitride. The first top semiconductor layer 30 is composed of a semiconductor material, which may be selected from, but is not limited to, silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. The semiconductor material can be polycrystalline or single crystalline, and is preferably single crystalline. For example, the semiconductor material may comprise single crystalline silicon. The thickness of the first top semiconductor layer 30 can be from 50 nanometers to 10 microns, although lesser and greater thicknesses can also be employed.

At least one first semiconductor device 32 is formed on the top surface of the first top semiconductor layer 30, which includes a semiconductor material. The at least one first semiconductor device 32 can be, for example, a field effect transistor, a bipolar transistor, a thyristor, a varactor, a diode, an electrical fuse, or any other type of semiconductor device known in the art. The upper side of the first substrate 2 is herein referred to as a front side, and the lower side of the first substrate 2 is herein referred to as a back side of the first substrate 2.

A first interconnect dielectric layer 40 can be formed over the at least one first semiconductor device 32 on the front side of the first top semiconductor layer 30. The first interconnect dielectric layer 40 can be composed of a dielectric material such as silicon oxide, silicon nitride, organosilicate glass (OSG), or any other dielectric material employed for constructing a metal interconnect layer in the art. The first interconnect dielectric layer 40 can be a single layer of homogeneous dielectric materials, or can be a plurality of layers having different compositions. At least one first metal interconnect structure 42 is formed in the first interconnect dielectric layer 40. Each of the at least one first metal interconnect structure 42 can be a conductive via structure, a conductive line structure, or a combination of at least one conductive via structure and at least one conductive line structure that are electrically connected among one another and electrically connected to one of the at least one first semiconductor device 32. The at least one first metal interconnect structure 42 is embedded in the first interconnect dielectric layer 40. The thickness of the first interconnect dielectric layer 40 can be from 100 nm to 20 microns, although lesser and greater thicknesses can also be employed.

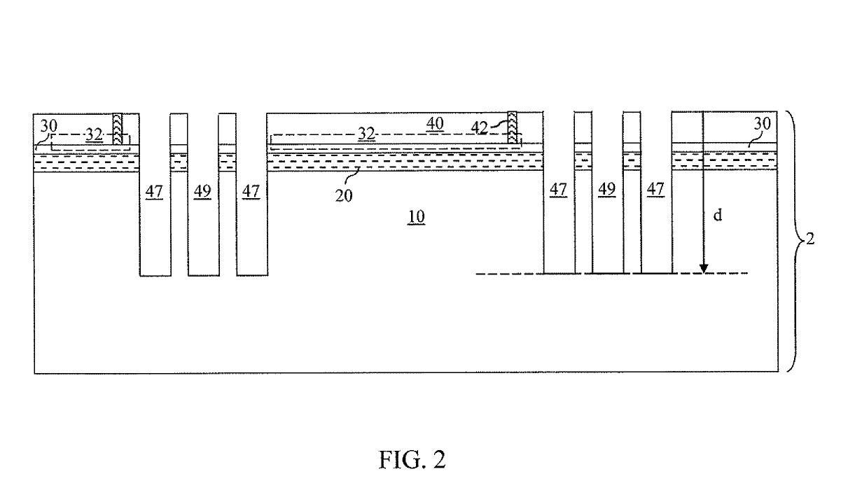

Referring to FIG. 2, a plurality of trenches is formed as at least one set of a first trench 49 and at least one second trench 47. For each set of trenches, the first trench 49 and the at least one second trench 47 extend from the top surface of first substrate 2 into the first substrate 2, i.e., from the top surface of the first interconnect dielectric layer 40 through the first interconnect dielectric layer 40, the first top semiconductor layer 30, the first buried insulator layer 20, and into the upper portion of the first handle substrate 10. Each of the first trench 49 and the at least one second trench 47 can have a bottom surface within the first handle substrate 10. The horizontal cross-sectional shapes of the first trench 49 and the at least one second trench are configured to enable shielding of electrical signals within a first through-substrate via (TSV) to be subsequently formed within the first trench 49 by at least one second through-substrate via (TSV) to be subsequently formed with in the at least one second trench 47.

Each set of trenches including a first trench 49 and at least one second trench 47 can be formed within the first substrate 2 by a combination of lithographic patterning of an etch mask (not shown) and a subsequent anisotropic etch. The anisotropic etch can be a reactive ion etch. During the anisotropic etch, each set of trenches (49, 47) is formed in area of opening in the etch mask. A plurality of sets of trenches (49, 47) can be formed within the first substrate 2 such that each set of trenches (49, 47) includes a first trench 49 and at least one second trench 47. Each first trench 49 and each of the at least one second trench 47 extend from the topmost surface of the first substrate 2 to a depth within the first handle substrate 10. The lateral dimensions of each of the first trench 49 and each of the at least one second trench 47 can be from 0.5 micron to 10 microns, although lesser and greater lateral dimensions can also be employed. In one embodiment, the depth d of each of the first trench 49 and each of the at least one second trench 47 from the topmost surface of the first substrate 2 can be from 30 micron to 600 microns, although lesser and greater depths can also be employed. In another embodiment, the depth d of each of the first trench 49 and each of the at least one second trench 47 from the topmost surface of the first substrate 2 can be from 10% to 90% of the thickness of the first substrate 2, although lesser and greater depths can also be employed.

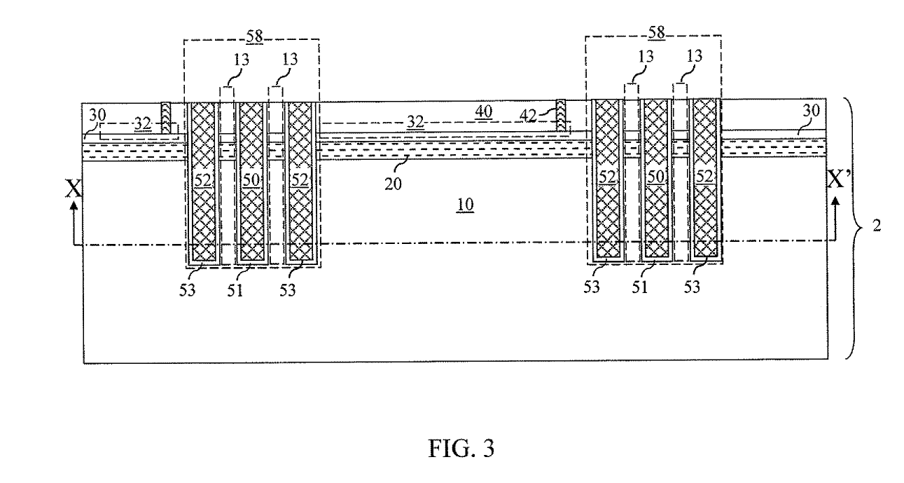

Referring to FIG. 3, a dielectric material layer and a conductive fill material are sequentially deposited in each set of trenches (49, 47) and planarized to remove excess materials above the topmost surface of the first interconnect dielectric layer 40. Remaining portions of the dielectric material layer within each first trench 49 constitute a first through-substrate via (TSV) liner 51, which contacts all sidewalls and bottom surfaces of a first trench 49. Remaining portions of the dielectric material layer within each of the at least one second trench 47 constitute at least one second through-substrate via (TSV) liner 53, which contacts all sidewalls and bottom surfaces of at least one second trench 47. Each first TSV liner 51 and each of the at least one second TSV liner 53 are dielectric liners that are composed of a same dielectric material. The dielectric material can be silicon oxide, silicon nitride, or any other dielectric material. Each first TSV liner 51 and each of the at least one second TSV liner 53 can be formed as a substantially conformal structure having substantially the same thickness throughout. The thickness of each first TSV liner 51 and each of the at least one second TSV liner 53 can be from 10 nm to 500 nm, although lesser and greater thicknesses can also be employed.

A first through-substrate via (TSV) structure 50 is formed within each first TSV liner 51 by a remaining portion of the conductive material after planarization. At least one second through-substrate via (TSV) structure 52 is formed within each at least one second TSV liner 53 by a remaining portion of the conductive material after planarization. Each first TSV structure 50 and each of the at least one second TSV structure 52 are composed of the same conductive material. Each shielded TSV structure 58 includes a first TSV structure 50, corresponding at least one second TSV structure 52, a first TSV liner 51, at least one second TSV liner 53, and a substrate material portion 13, which is a volume of the first substrate 2 between the first TSV liner 51 and the at least one second TSV liner 53. Each first TSV structure 50 and each of the at least one second TSV structure can be composed of a conductive material, which can be an elemental metal, an intermetallic alloy, a conductive metal nitride, a doped semiconductor material, or a combination thereof. In one embodiment, each first TSV structure 50 and each of the at least one second TSV structure are composed of W, Au, Ag, Cu, Ni, or an alloy thereof.

Within each shielded TSV structure 58, the first TSV structure 50 is composed of the conductive material and is electrically insulated from the substrate 2, i.e., the collection of the first handle substrate 10, the first buried insulator layer 20, the first top semiconductor layer 30, and the first interconnect dielectric layer 40. Within each shielded TSV structure 58, the at least one second TSV structure 52 is composed of the conductive material and is configured to shield electrical signals within the corresponding first TSV structure 50 from external electromagnetic signals.

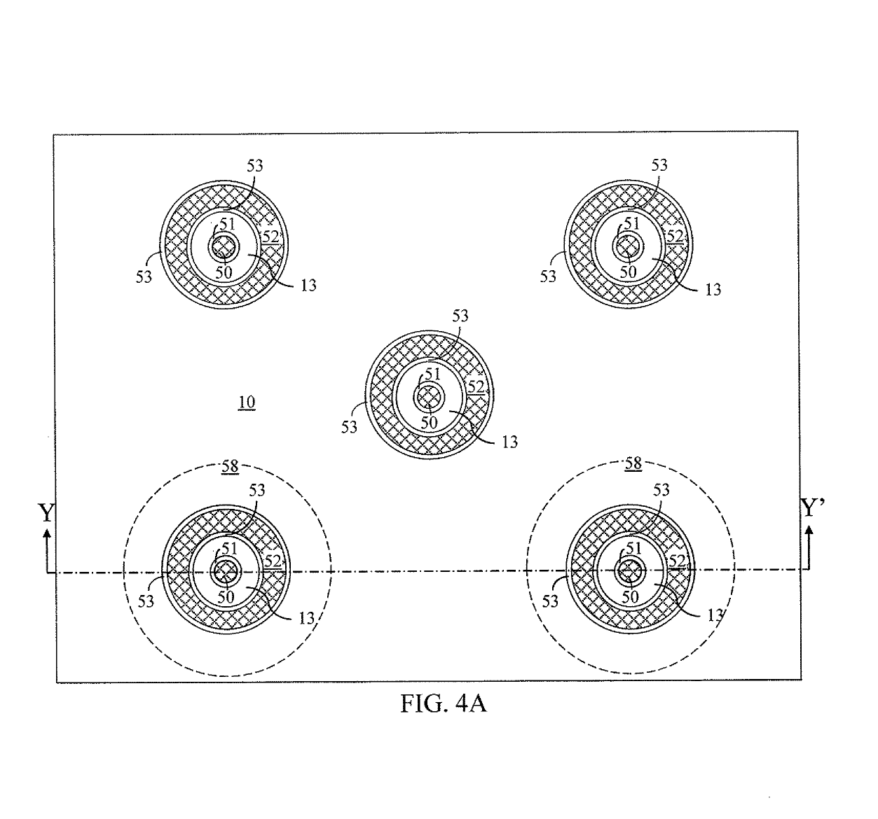

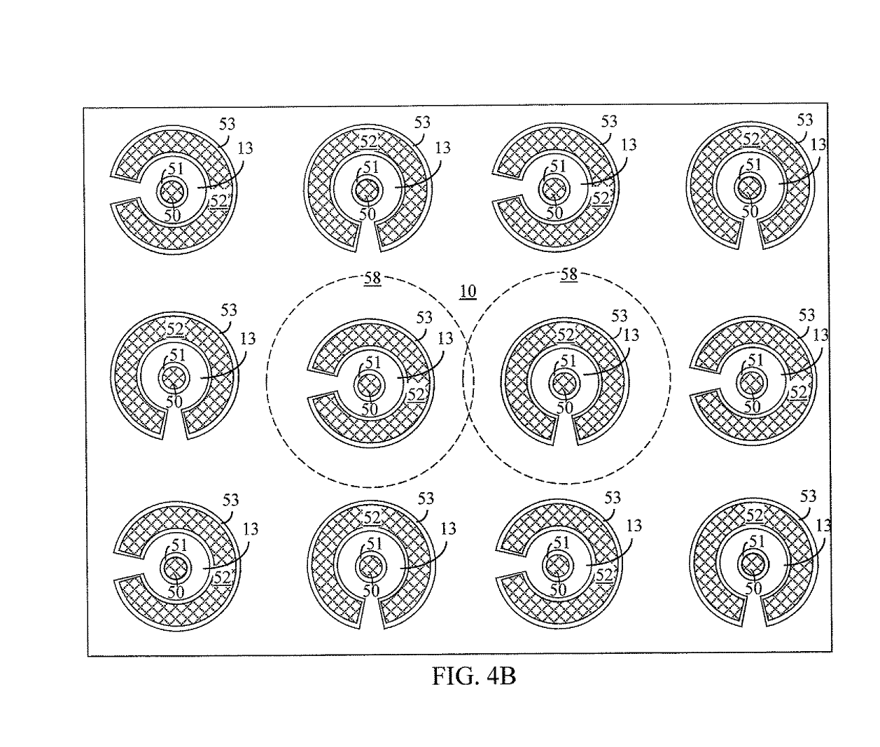

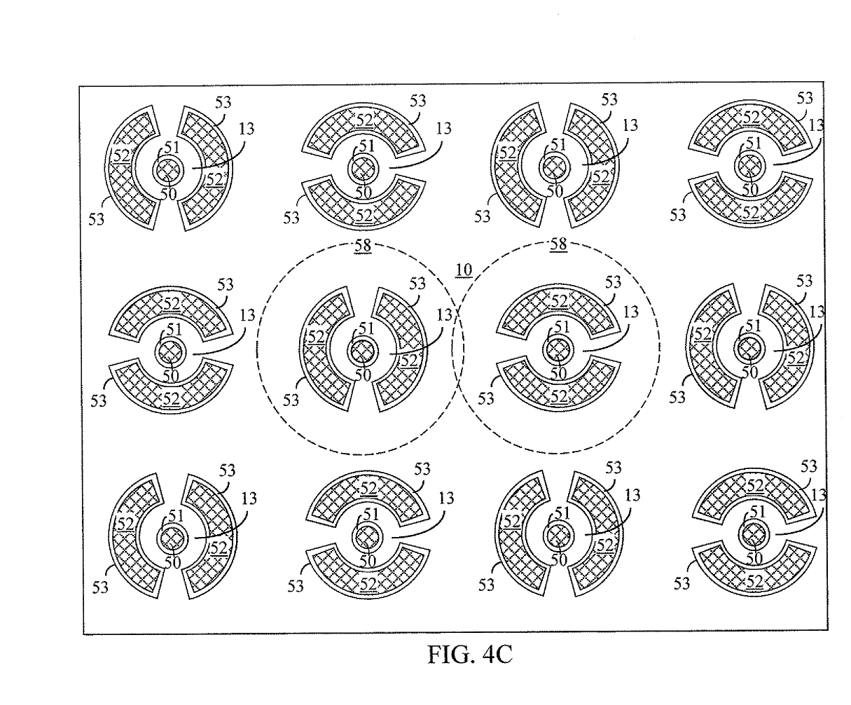

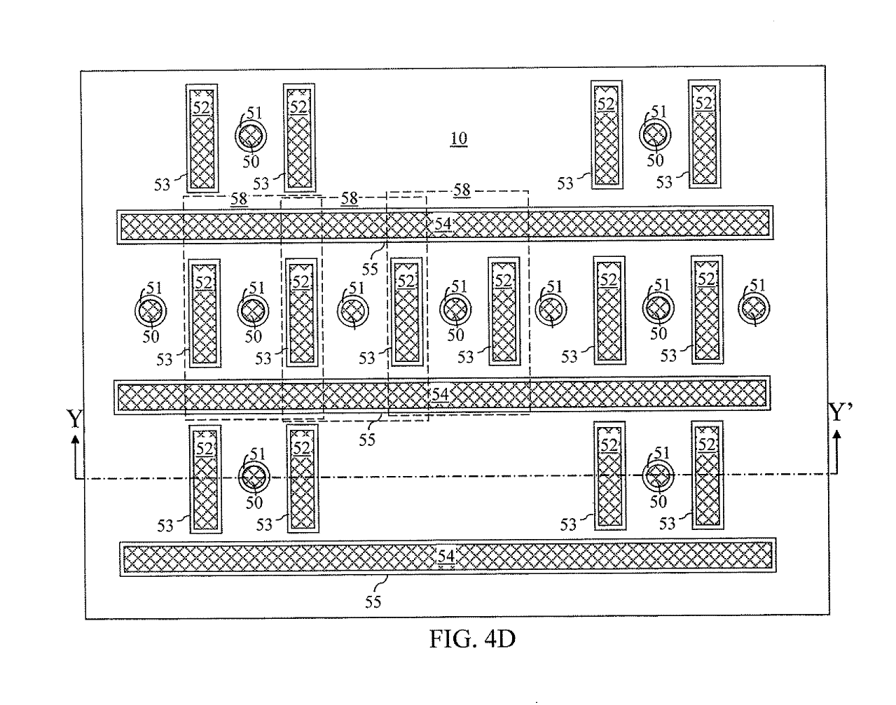

Referring to FIG. 4A, a horizontal cross-sectional view of the first exemplary semiconductor structure along the plane X-X′ in FIG. 3 shows five shielded TSV structures 58, each of which includes a first TSV structure 50, at least one second TSV structure 52, a first TSV liner 51, at least one second TSV liner 53, and a substrate material portion 13. The Y-Y′ plane of FIG. 4A is the vertical cross-sectional plane of FIG. 3. The at least one second TSV structure 52 can be a contiguous unitary conductive structure that laterally surrounds the first TSV structure 50 at all azimuthal angles within each shielded TSV structure 58. For example, the at least one second TSV structure 52 can be a cylindrical structure having substantially the same horizontal cross-sectional area independent of the height of the plane of the horizontal cross-sectional view.

The at least one second TSV structure 52 is spaced from the first TSV structure 50 by the substrate material portion 13, which is a laterally enclosing structure having the same material composition as the first substrate 2. Specifically, the substrate material portion 13 includes a portion of the first handle substrate 10, a portion of the first buried insulator layer 20, a portion of the first top semiconductor layer 30, and a portion of the first interconnect dielectric layer 40. The substrate material portion 13 of FIG. 4A is laterally spaced from the rest of the materials of the first substrate (10, 20, 30, 40), and is contiguously connected to the rest of the materials of the first substrate (10, 20, 30, 40) only at a bottom end of the substrate material portion 13 that is coplanar with bottom surfaces of the first TSV structure 50 and the at least one second TSV structure 52. Within each shielded TSV structure 58, the first TSV structure 50 is laterally surrounded by structures that includes, from inside to outside, a first dielectric liner 51, the laterally enclosing structure of the substrate material portion 13, an inner portion of the at least one second dielectric liner 53, the contiguous unitary conductive structure of the at least one second TSV structure 52, an outer portion of the at least one second dielectric liner 53, and the first substrate (10, 20, 30, 40).

Referring to FIG. 4B, a horizontal cross-sectional view of a first variation of the first exemplary semiconductor structure along a plane equivalent to the plane X-X′ in FIG. 3 is shown. FIG. 4B shows twelve shielded TSV structures 58, each of which includes a first TSV structure 50, at least one second TSV structure 52, a first TSV liner 51, at least one second TSV liner 53, and a substrate material portion 13. The at least one second TSV structure 52 can be a contiguous unitary conductive structure that laterally surround the first TSV structure 50 at a range of azimuthal angles within each shielded TSV structure 58. The range of azimuthal angles does not include all possible azimuthal angles. For example, the at least one second TSV structure 52 can be a curved plate structure having a single opening in one azimuthal direction and having substantially the same horizontal cross-sectional area independent of the height of the plane of the horizontal cross-sectional view. In general, the at least one second TSV structure 52 is not present at least within a range of azimuthal angles from a center of a horizontal cross-sectional area of the first TSV structure 50. The magnitude of the range is less than 90 degrees. The azimuthal angles within the range can be different among shielded TSV structures 58 in order to minimize the effect of the electromagnetic signals that escape from first TSV structures 50 through lateral openings in each of the second TSV structures 52 when a plurality of shielded TSV structures 58 are employed. Each of the at least one second TSV structure 52 as a contiguous unitary conductive structure is present at all azimuthal angles outside the range of azimuthal angles corresponding to the lateral opening in each second TSV structure 52.

The at least one second TSV structure 52 is spaced from the first TSV structure 50 by the substrate material portion 13, which is laterally enclosing structure having the same material composition as the first substrate 2. Specifically, the substrate material portion 13 includes a portion of the first handle substrate 10, a portion of the first buried insulator layer 20, a portion of the first top semiconductor layer 30, and a portion of the first interconnect dielectric layer 40. The substrate material portion 13 of FIG. 4B can be laterally contiguous with the rest of the first substrate (10, 20, 30, 40) through the lateral opening in the curved plate structure of the at least one second TSV structure 52. Within each shielded TSV structure 58, the first TSV structure 50 is laterally surrounded by a first dielectric liner 51. Within each shielded TSV structure 58, the substrate material portion 13 laterally separates the collection of the at least one second dielectric liner 53 and the contiguous unitary conductive structure of the at least one second TSV structure 52.

The substrate material portion 13 is laterally contiguous with the first substrate (10, 20, 30, 40). Due to the structural unity of each substrate material portion 13 with the rest of the first substrate (10, 20, 30, 40), the rest of the first substrate (10, 20, 30, 40) provides enhanced mechanical support to the substrate material portion(s) 13 and holds each substrate material portion 13 in a fixed position relative to the rest of the first substrate (10, 20, 30, 40) during subsequent thermal cycling.

Referring to FIG. 4C, a horizontal cross-sectional view of a second variation of the first exemplary semiconductor structure along a plane equivalent to the plane X-X′ in FIG. 3 is shown. FIG. 4C shows twelve shielded TSV structures 58, each of which includes a first TSV structure 50, at least one second TSV structure 52, a first TSV liner 51, at least one second TSV liner 53, and a substrate material portion 13. The at least one second TSV structure 52 is a plurality of second TSV structures that are azimuthally spaced from each other by portions of the first substrate 2. The plurality of second TSV structures in each of the at least one second TSV structure 52 is axially spaced from the first TSV structure 50 by another portion of the first substrate 2. The portions of the first substrate 2 that azimuthally space the plurality of second TSV structures and the other portion of the first substrate 2 that axially spaces the first TSV substrate 50 from the plurality of second TSV structures are contiguous with one another, and are collectively referred to as a substrate material portion 13.

Within each shielded TSV structure 58, the at least one second TSV structure 52 is a plurality of conductive structure that partially surrounds the first TSV structure 50 laterally at a plurality of ranges of azimuthal angles. The ranges of azimuthal angles do not include all possible azimuthal angles and has a plurality of gaps between the ranges. While the at least one second TSV structure 52 is described as a pair of curved plate structures having two openings in azimuthal directions, the at least one second TSV structure 52 in a single shielded TSV structure 58 can include any number N of discrete curved plate structures, in which the number N is an integer greater than 1. Because the at least one second trench 47 is formed by an anisotropic etch process, each of the plurality of second TSV structures has substantially the same horizontal cross-sectional area independent of the height of the plane of the horizontal cross-sectional view. The at least one second TSV structure 52 is not present within a plurality of ranges of azimuthal angles from a center of a horizontal cross-sectional area of the first TSV structure 50 that correspond to the lateral openings between the plurality of second TSV structures. The azimuthal angles within the range for absence of the at least one second TSV structure 52 can be different among shielded TSV structures 58 in order to minimize the effect of the electromagnetic signals that escape from first TSV structures 50 through lateral openings in each of the second TSV structures 52 when a plurality of shielded TSV structures 58 are employed. Each of the at least one second TSV structure 52 as a plurality of conductive structure is present at all azimuthal angles outside the range of azimuthal angles corresponding to the lateral openings in each of the at least one second TSV structure 52 in any given shielded TSV structures 58.

The at least one second TSV structure 52 is spaced from the first TSV structure 50 by the substrate material portion 13, which is laterally enclosing structure having the same material composition as the first substrate 2. Specifically, the substrate material portion 13 includes a portion of the first handle substrate 10, a portion of the first buried insulator layer 20, a portion of the first top semiconductor layer 30, and a portion of the first interconnect dielectric layer 40. The substrate material portion 13 of FIG. 4C can be laterally contiguous with the rest of the first substrate (10, 20, 30, 40) through the lateral openings in the curved plate structures of the at least one second TSV structure 52. Within each shielded TSV structure 58, the first TSV structure 50 is laterally surrounded by a first dielectric liner 51. Within each shielded TSV structure 58, the substrate material portion 13 laterally separates the collection of the at least one second dielectric liner 53 and the plurality of conductive structures of the at least one second TSV structure 52.

The substrate material portion 13 is laterally contiguous with the first substrate (10, 20, 30, 40). Due to the structural unity of each substrate material portion 13 with the rest of the first substrate (10, 20, 30, 40), the rest of the first substrate (10, 20, 30, 40) provides enhanced mechanical support to the substrate material portion(s) 13 and holds each substrate material portion 13 in a fixed position relative to the rest of the first substrate (10, 20, 30, 40) during subsequent thermal cycling.

Referring to FIG. 4D, a horizontal cross-sectional view of a third variation of the first exemplary semiconductor structure is shown along a plane corresponding to X-X′ plane in FIG. 3. The Y-Y′ plane in FIG. 4D corresponds to the vertical cross-sectional plane of FIG. 3. Each of a plurality of shielded TSV structures 58 includes a first TSV structure 50, at least one second TSV structure 52, at least one portion of at least one third TSV structure 54, a first TSV liner 51, at least one second TSV liner 53, at least one portion of at least one third TSV liner 55, and a portion of the first substrate 2 that is located between the first TSV structure 50 and any of the at least one second TSV structure 52 and at least one third TSV structure 54.

In one embodiment, the at least one second TSV structure 52 is a plurality of second TSV structures having lengthwise edges that are parallel among one another. The at least one third TSV structure 54 is a plurality of third TSV structures having lengthwise edge that are parallel among one another and are not parallel to the at least one second TSV structures 52. A second TSV structure 52 can belong to a single shielded TSV structure 55 or plurality of shielded TSV structures 55. A third TSV structure 54 can include a plurality of portions that belong to different shielded TSV structures 58. The at least one shield TSV structure 58 can be a plurality of shield TSV structures including a plurality of first TSV structures 50, a plurality of second TSV structures 52, and a plurality of third TSV structures 54. The plurality of second TSV structures 52 can be located between each pair of first TSV structures among the plurality of first TSV structures 50 to intercept all direct signal paths between the pair of first TSV structures. Further, the plurality of third TSV structures 54 can be located between each pair of first TSV structures among the plurality of first TSV structures 50 to intercept all direct signal paths between the pair of first TSV structures.

The at least one second TSV structure 52 and the at least one third TSV structure 54 are spaced from each first TSV structure 50 by a substrate material portion, which is a portion of the first substrate 2. All substrate material portions are of integral construction with the rest of the first substrate 2. Thus, the first substrate 2 is a single unitary matrix in which the shielded TSV structures 58 are embedded. Each of the at least one first TSV structure 50, each of the at least one second TSV structure 52, and each of the third TSV structure 54 are embedded in the singe unitary matrix of the first substrate 2.

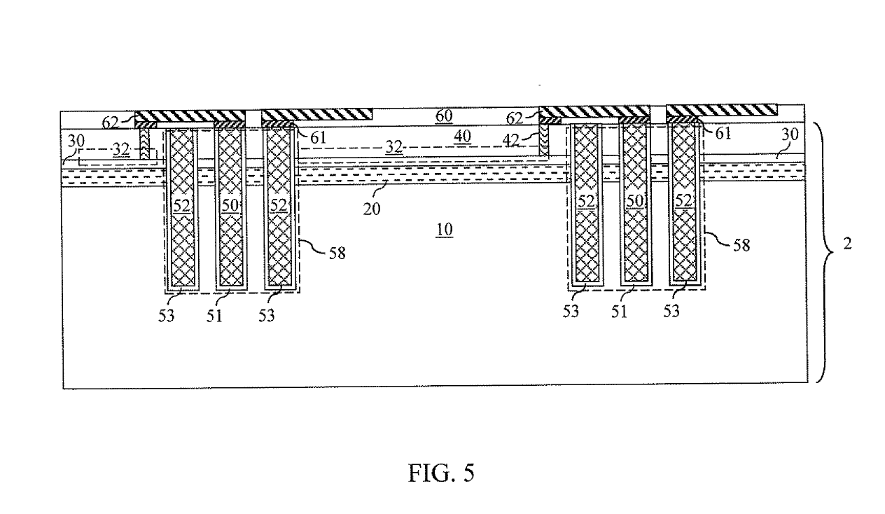

Referring to FIG. 5, the first exemplary semiconductor structure or any variation thereof is subjected to further processing steps to form a first front side dielectric layer 60 on the first interconnect dielectric layer 40. While the first embodiment is described employing the structures derived from the first exemplary structure of FIGS. 3 and 4A, structures corresponding to the various variations of the first exemplary structure can be readily obtained by employing the same processing steps. The first front side dielectric layer 60 is composed of a dielectric material such as silicon oxide, silicon nitride, silicon oxynitride, or a combination thereof. First front side metal pads 62 are formed in the first front side dielectric layer 60 such that each of the first front side metal pads 62 is electrically connected to at least one of the at least one first TSV structure 50. Further, the first front side metal pads 62 can be electrically connected to at least one of the at least one first metal interconnect structure 42. The first front side metal pads 62 are embedded in the first front side dielectric layer 60. The thickness of the first front side dielectric layer 60 can be from 0.2 micron to 10 microns, although lesser and greater thicknesses can also be employed.

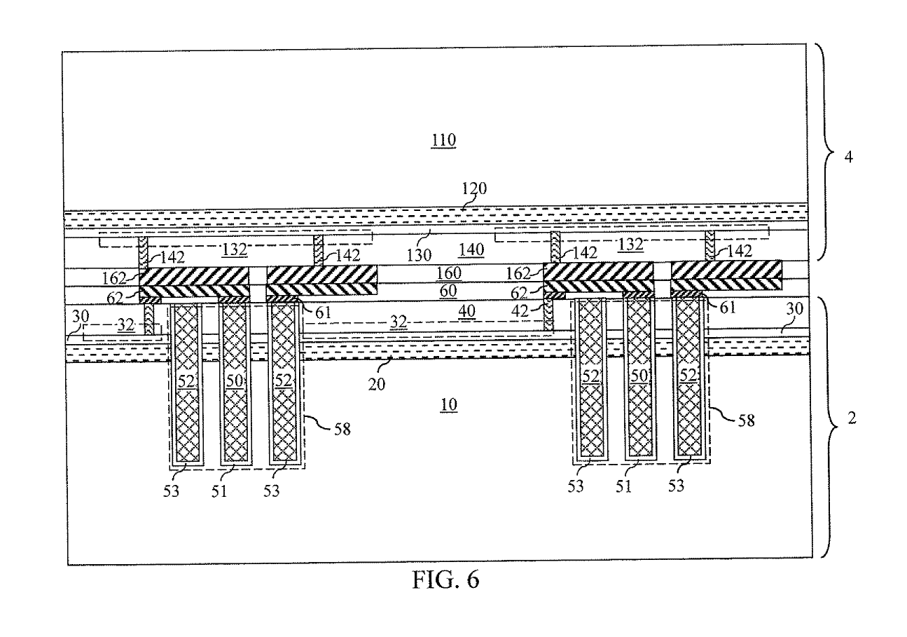

Referring to FIG. 6, a second substrate 4 is bonded to the first substrate 2 by methods known in the art. The first substrate 2 and the second substrate 4 collectively constitute a bonded substrate 8. The front side of the first substrate 2 is bonded to the front side or the back side of the second substrate 4. For example, if the front side of the first substrate 2 is bonded to the front side of the second substrate 4, second front side metal pads 162 that are embedded in a second front side dielectric layer 160 are formed on the second substrate 4. In this case, the second front side metal pads 162 in the second substrate 4 are bonded to the first front side metal pads 62 in the first substrate 2.

The second substrate 4 can include a semiconductor-on-insulator (SOT) substrate, a bulk semiconductor substrate, or a hybrid substrate including at least one SOI portion and at least one bulk portion. If the second substrate 4 includes an SOI substrate, the SOI substrate can contain, from bottom to top, a second handle substrate 110, a second buried insulator layer 120, and a second top semiconductor layer 130.

The second handle substrate 110 can include a semiconductor material, a dielectric material, a conductive material, or a combination thereof. The second buried insulator layer 120 includes a dielectric material. The second top semiconductor layer 130 is composed of a semiconductor material that can be employed for the first top semiconductor layer 30 as described above. The thickness of the second top semiconductor layer 130 can be from 50 nanometers to 10 microns, although lesser and greater thicknesses can also be employed.

At least one second semiconductor device 132 is present on the top surface of the second top semiconductor layer 130. A second interconnect dielectric layer 140 can be present over the at least one second semiconductor device 132 on the front side of the second top semiconductor layer 130. The second interconnect dielectric layer 140 can be composed of any dielectric material that can be employed for the first interconnect dielectric layer 40 as described above. At least one second metal interconnect structure 142 is formed in the second interconnect dielectric layer 140. Each of the at least one second metal interconnect structure 142 can be a conductive via structure, a conductive line structure, or a combination of at least one conductive via structure and at least one conductive line structure that are electrically connected among one another and electrically connected to one of the at least one second semiconductor device 132. The at least one second metal interconnect structure 142 is embedded in the second interconnect dielectric layer 140. The thickness of the second interconnect dielectric layer 140 can be from 100 nm to 20 microns, although lesser and greater thicknesses can also be employed.

If the back side of the second substrate 4 is bonded to the front side of the first substrate 2, through-substrate via (TSV) structures (not shown) in the second substrate 4 can be employed to provide electrical connection between the first front side metal pads 62 in the first substrate 2 and the semiconductor devices located on the front side of the second substrate 4.

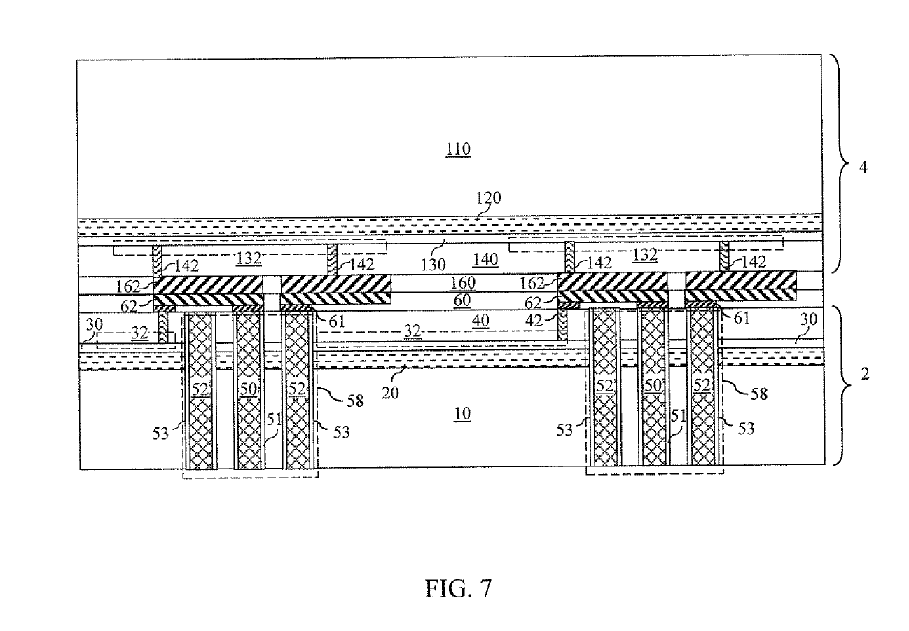

Referring to FIG. 7, the back side surface, i.e., the bottommost surface, of the first substrate 2 is recessed to expose horizontal end surfaces of each first TSV structure 50 and each of the at least one second TSV structure 52 (and each of the at least one third TSV structure 54, if present). The horizontal end surfaces of each first TSV structure 50 and each of the at least one second TSV structure 52 are the bottommost surfaces of the corresponding first TSV structure 50 and the corresponding at least one second TSV structure 52 in FIG. 6. The recessing of the back side surface of the first substrate 2 can be effected, for example, by chemical mechanical planarization (CMP), mechanical grinding, dry etching, or a combination thereof. Because the horizontal portions of each first TSV liner 51 and each of the at least one second TSV liner 53 (and each of the at least one third TSV liner 55, if present) are removed, each first TSV liner 51 and each of the at least one second TSV liner 53 become cylindrical structures that are topologically homeomorphic to a torus, i.e., a structure that can be continuously stretched into a shape of a torus without forming a new spatial singularity or destroying an existing spatial singularity. In one embodiment, the recessing of the back side surface of the first substrate 2 is performed such that the exposed end surfaces of each first TSV structure 50, each of the at least one second TSV structure 52, each first TSV liner 51, and each of the at least one second TSV liner 53 are coplanar with the back side surface of the first handle substrate 10 at the end of the recessing.

After recessing the back side surface of the first substrate 2, remaining portions of the conductive material in the plurality of trenches constitute at least one shielded through-substrate via (TSV) structure 58 embedded in the first substrate 2. Each of the at least one shielded TSV structure 58 includes a first TSV structure 50 and at least one second TSV structure 52, and optionally at least one third TSV structure 54 depending on embodiments. The first TSV structure 50 and the at least one second TSV structure 52 are electrically isolated from the first substrate 2, and the at least one second TSV structure 52 is configured to shield electrical signals within the first TSV structure 50 from external electromagnetic signals and to shield any other first TSV structure 50 from any electrical signals emanating from the first TSV structure 50 within the at least one second TSV structure 52. Each of the first TSV structure 50 and the at least one second TSV structure 52 include a same conductive material and is electrically insulated from the first substrate 2. Each of the first TSV structure 50 and the at least one second TSV structure 52 extending at least from the interface between the first top semiconductor layer 30 and the first interconnect dielectric layer 40 to a back side surface of the first substrate 2, which is the bottommost surface of the first handle substrate 10 after planarization.

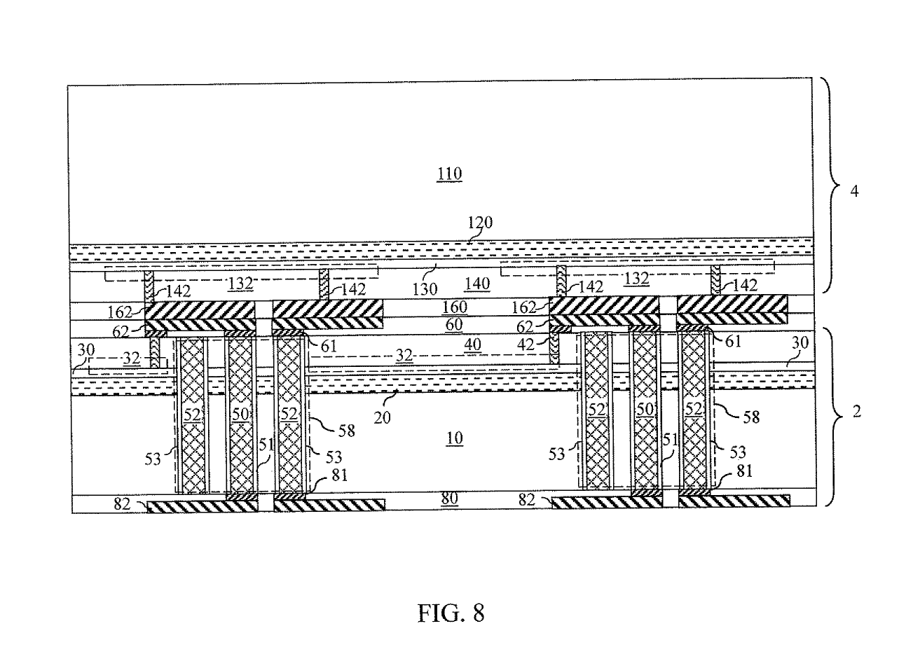

Referring to FIG. 8, a first back side dielectric layer 80 is formed on the back side of the first substrate 2. The first back side dielectric layer 80 can be formed directly on the end surfaces of the first TSV structure(s) 50 and the at least one second TSV structure 52. The first back side dielectric layer 80 is composed of a dielectric material such as silicon oxide, silicon nitride, silicon oxynitride, or a combination thereof. First back side metal interconnect structures 81 can be optionally formed in the first back side dielectric layer 80. First back side metal pads 82 are formed in the first back side dielectric layer 80 such that each of the first back side metal pads 82 is electrically connected to one of the first TSV structure(s) 50 or one of the at least one second TSV structure 52. The first back side metal pads 82 are embedded in the first back side dielectric layer 80. The thickness of the first back side dielectric layer 80 can be from 0.2 micron to 10 microns, although lesser and greater thicknesses can also be employed.

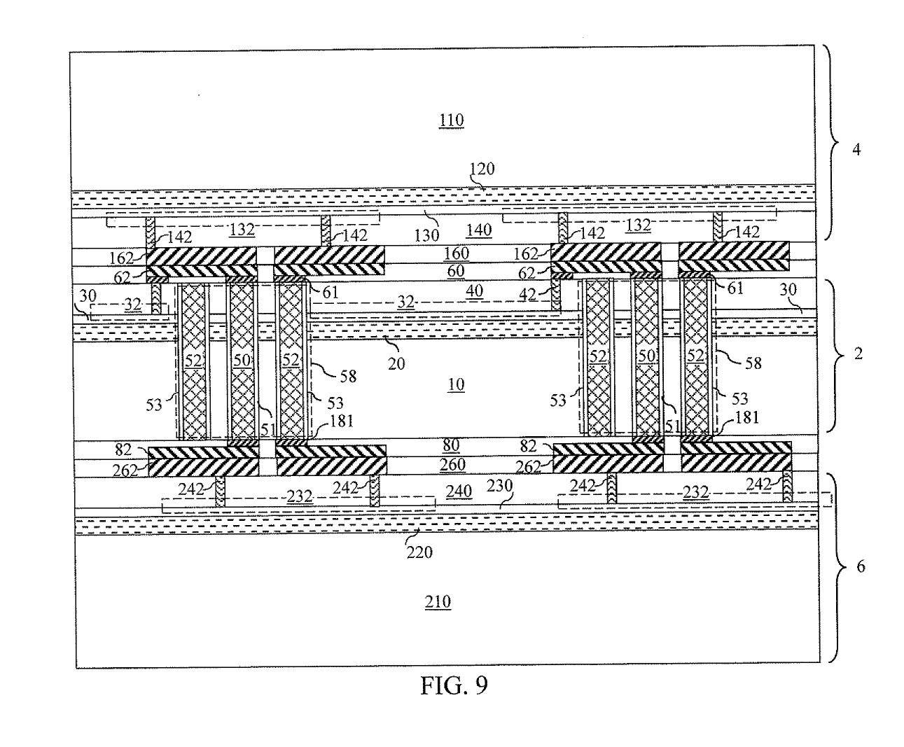

Referring to FIG. 9, a third substrate 6 is bonded to the first substrate 2 by methods known in the art. The back side of the first substrate 2 is bonded to the front side or the back side of the third substrate 6. For example, if the back side of the first substrate 2 is bonded to the front side of the third substrate 6, the third substrate 6 includes third front side metal pads 262 that are embedded in a third front side dielectric layer 260. In this case, the third front side metal pads 262 in the third substrate 6 are bonded to the first back side metal pads 82 in the first substrate 2.

The third substrate 6 can include a semiconductor-on-insulator (SOI) substrate, a bulk semiconductor substrate, or a hybrid substrate including at least one SOI portion and at least one bulk portion. If the third substrate 6 includes an SOI substrate, the SOI substrate can contain, from bottom to top, a third handle substrate 210, a third buried insulator layer 220, and a third top semiconductor layer 230.

The third handle substrate 210 can include a semiconductor material, a dielectric material, a conductive material, or a combination thereof. The third buried insulator layer 220 includes a dielectric material. The third top semiconductor layer 230 is composed of a semiconductor material that can be employed for the first top semiconductor layer 30 as described above. The thickness of the third top semiconductor layer 230 can be from 50 nanometers to 10 microns, although lesser and greater thicknesses can also be employed.

At least one third semiconductor device 232 is present on the top surface of the third top semiconductor layer 230. A third interconnect dielectric layer 240 can be present over the at least one third semiconductor device 232 on the front side of the third top semiconductor layer 230. The third interconnect dielectric layer 240 can be composed of any dielectric material that can be employed for the first interconnect dielectric layer 40 as described above. At least one third metal interconnect structure 242 is formed in the third interconnect dielectric layer 240. Each of the at least one third metal interconnect structure 242 can be a conductive via structure, a conductive line structure, or a combination of at least one conductive via structure and at least one conductive line structure that are electrically connected among one another and electrically connected to one of the at least one third semiconductor device 232. The at least one third metal interconnect structure 242 is embedded in the third interconnect dielectric layer 240. The thickness of the third interconnect dielectric layer 240 can be from 100 nm to 20 microns, although lesser and greater thicknesses can also be employed.

If the back side of the third substrate 6 is bonded to the front side of the first substrate 2, through-substrate via (TSV) structures (not shown) in the third substrate 6 can be employed to provide electrical connection between the first back side metal pads 82 in the first substrate 2 and the semiconductor devices located on the front side of the third substrate 6.

The first exemplary semiconductor structure includes a first substrate 2, which includes a semiconductor layer in the form of the first top semiconductor layer 30 and an interconnect dielectric layer in the form of the first interconnect dielectric layer 40. At least one first semiconductor device 32 is located at an interface between the semiconductor layer and the interconnect dielectric layer. At least one shielded through-substrate via (TSV) structure 58 is embedded in the first substrate 2. Each of the at least one shielded TSV structure 58 includes a first TSV structure 50 and at least one second TSV structure 52, each composed of a conductive material that can be selected from an elemental metal, an intermetallic alloy, a conductive metal nitride, a doped semiconductor material, and a combination thereof. For example, the conductive material can be Au, Ag, Cu, W, Al, or a combination thereof. Each of the first TSV structure 50 and the at least one second TSV structure 52 is electrically insulated from the first substrate 2, and extends at least from said interface between the first top semiconductor layer 30 and the first interconnect dielectric layer 40 to the back side surface of the first substrate 2.

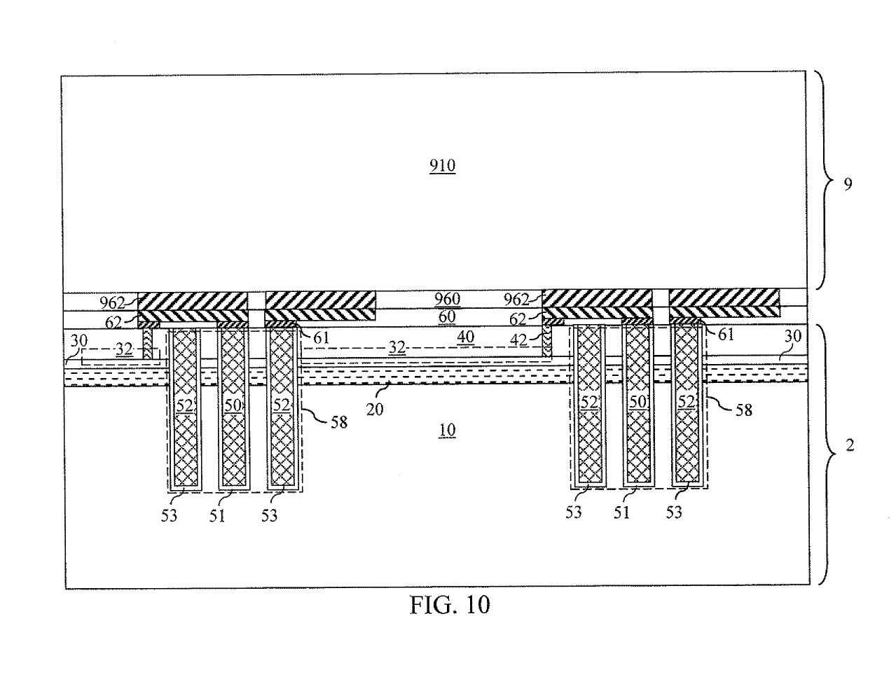

Referring to FIG. 10, a second exemplary semiconductor structure according to a second embodiment of the present invention is derived from the first exemplary structure of FIG. 5 or any variation of the first exemplary structure at a processing step corresponding to the step of FIG. 5 by bonding a temporary substrate 9 to the first substrate 2. The temporary substrate 9 can be bonded to the first substrate 2 by methods known in the art. The first substrate 2 and the temporary substrate 9 collectively constitute a bonded substrate. The front side of the first substrate 2 is bonded to the temporary substrate 9. For example, terminal front side metal pads 962 that are embedded in a terminal front side dielectric layer 960 are formed on the front side of the temporary substrate 9. Subsequently, the terminal front side metal pads 962 in the temporary substrate 9 are bonded to the first front side metal pads 62 in the first substrate 2.

The temporary substrate 9 includes a temporary handle substrate 910, which can include a semiconductor material, a dielectric material, a conductive material, or a combination thereof. The thickness of the temporary substrate can be from 200 microns to 1,000 microns, although lesser and greater thicknesses can also be employed.

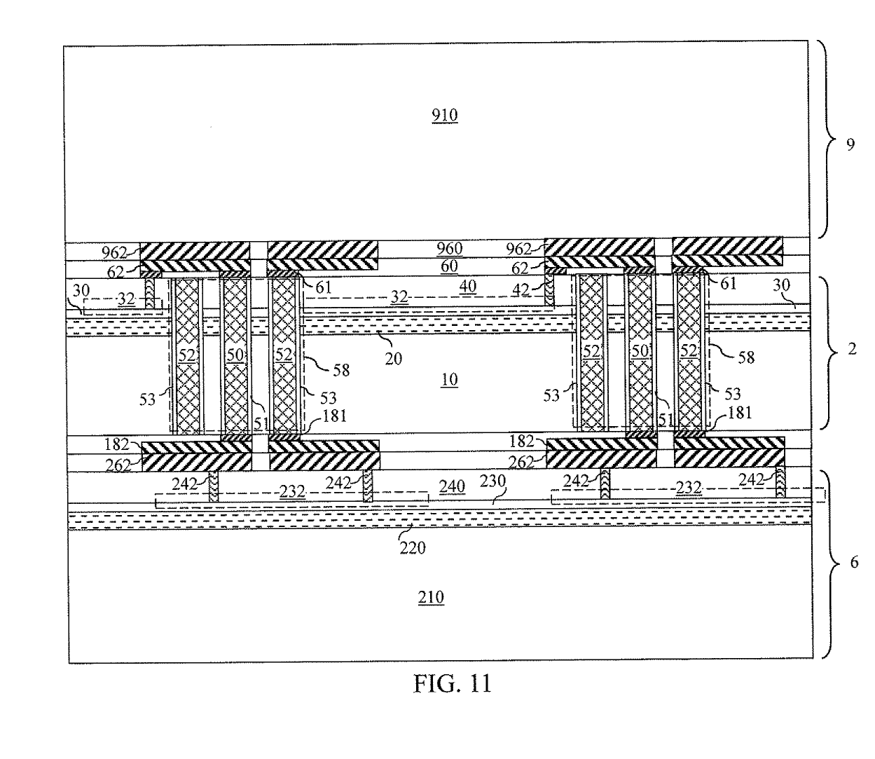

Referring to FIG. 11, processing steps of FIGS. 7-9 are performed in the same manner as in the first embodiment to recess the back side surface of the first substrate 2 and to bond a third substrate 6.

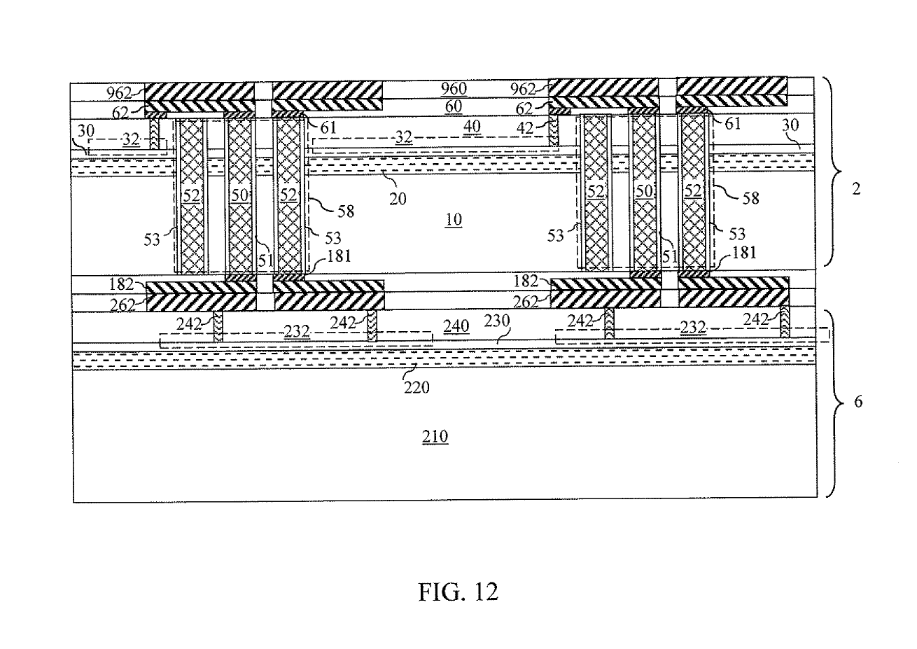

Referring to FIG. 12, the temporary substrate 9 is removed from the assembly of the substrates. The removal of the temporary substrate 9 can be effected, for example, by cleaving or by planarization of the temporary substrate 9. The at least one shielded TSV structure 58 in the first substrate 2 can have all of the features of the first exemplary structure in FIG. 9.

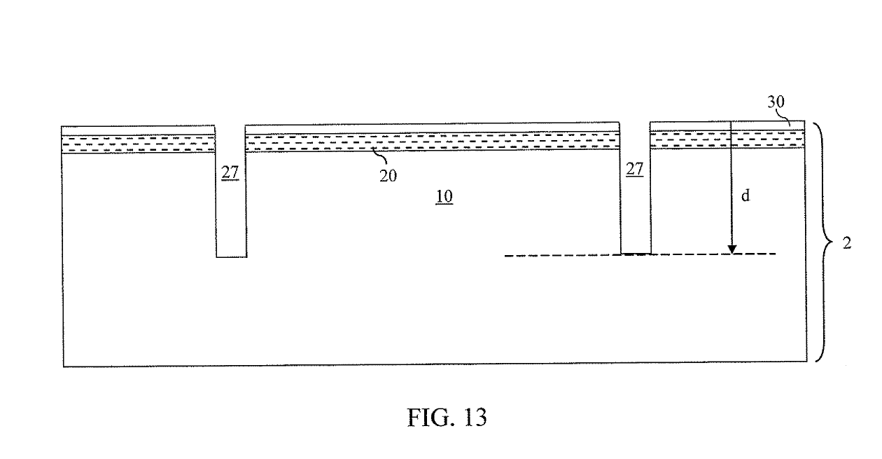

Referring to FIG. 13, a third exemplary semiconductor structure according to a third embodiment of the present invention includes a first substrate 2, which includes a first handle substrate 10, a first buried insulator layer 20, and a first top semiconductor layer 30. The first handle substrate 10 of the third embodiment is composed of a semiconductor material, which can be a polycrystalline semiconductor material or a single crystalline semiconductor material. The first buried insulator layer 20 and the first top semiconductor layer 30 can be composed of the same type of materials as in the first embodiment.

At least one deep trench 27 is formed from the top surface of the first substrate 2 through the first top semiconductor layer 30, the first buried insulator layer 20, and an upper portion of the first handle substrate 10. The at least one deep trench 27 extend from the top surface of first substrate 2 into the first substrate 2, i.e., from the top surface of the first top semiconductor layer 30 through the first buried insulator layer 20 and into the upper portion of the first handle substrate 10. Each of the at least one trench 27 has a bottom surface within the first handle substrate 10.

The lateral dimensions of each of the at least one deep trench 27 can be from 0.5 micron to 10 microns, although lesser and greater lateral dimensions can also be employed. In one embodiment, the depth d of each of the at lest one deep trench 27 from the topmost surface of the first substrate 2 can be from 30 micron to 600 microns, although lesser and greater depths can also be employed. In another embodiment, the depth d of each of the at least one deep trench 27 from the topmost surface of the first substrate 2 can be from 10% to 90% of the thickness of the first substrate 2, although lesser and greater depths can also be employed.

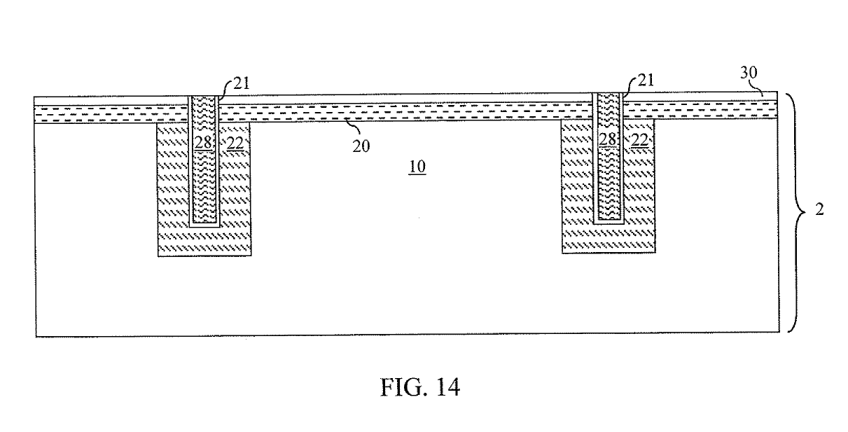

Referring to FIG. 14, a doped buried plate 22 is formed around sidewalls and a bottom surface of each of the at least one deep trench 27. The doped buried plate 22 is a doped semiconductor portion composed of dopants and the semiconductor material of the first handle substrate 10. The remaining portion of the first handle substrate 10 can be composed of an undoped semiconductor material. The doped buried plate 22 can be formed by introducing dopant atoms such as B, Ga, In, P, As, and Sb into a portion of the first handle substrate 10 within the proximity from sidewalls and a bottom surface of each of the at least one deep trench 27. The dopant atoms can be introduced, for example, by outdiffusion from a doped silicate glass, gas phase doping, plasma doping, or a combination thereof. The extent of diffusion of the dopant atoms can be from 100 nm to 2 microns, and typically from 200 nm to 1 micron, although lesser and greater extent of diffusion can also be employed.

Subsequently, a dielectric material layer and a temporary fill material are sequentially deposited in each of the at least one deep trench 27 and planarized to remove excess materials above the topmost surface of the first top semiconductor layer 30. Remaining portions of the dielectric material layer within each deep trench 27 constitute a through-substrate via (TSV) liner 21, which contacts all sidewalls and bottom surfaces of a deep trench 27. Each TSV liner 21 is a dielectric liner that is composed of a dielectric material, which can be, for example, silicon oxide, silicon nitride, or any other dielectric material. Each TSV liner 21 can be formed as a substantially conformal structure having substantially the same thickness throughout. The thickness of each TSV liner 21 can be from 10 nm to 500 nm, although lesser and greater thicknesses can also be employed.

A temporary fill structure 28 is formed within each TSV liner 21 by a remaining portion of the conductive material after planarization. Each temporary fill structure 28 is composed of a material that is different from the material of the at least one TSV liner 21. The material of the at least one temporary fill structure 28 can be a semiconductor material, a conductive material, or a dielectric material. For example, the material of the at least one temporary fill structure 28 can be polysilicon or a polycrystalline silicon germanium alloy.

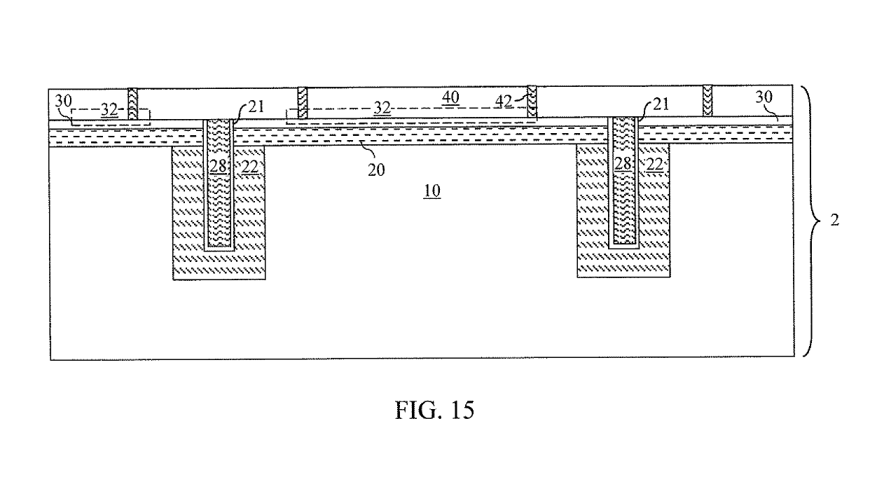

Referring to FIG. 15, at least one first semiconductor device 32 is subsequently formed on the top surface of the first top semiconductor layer 30, which includes a semiconductor material. The at least one first semiconductor device 32 can be, for example, a field effect transistor, a bipolar transistor, a thyristor, a varactor, a diode, an electrical fuse, or any other type of semiconductor device known in the art. A first interconnect dielectric layer 40 can be formed over the at least one first semiconductor device 32 on the front side of the first top semiconductor layer 30 in the same manner as in the first embodiment. At least one first metal interconnect structure 42 is formed in the first interconnect dielectric layer 40 in the same manner as in the first embodiment.

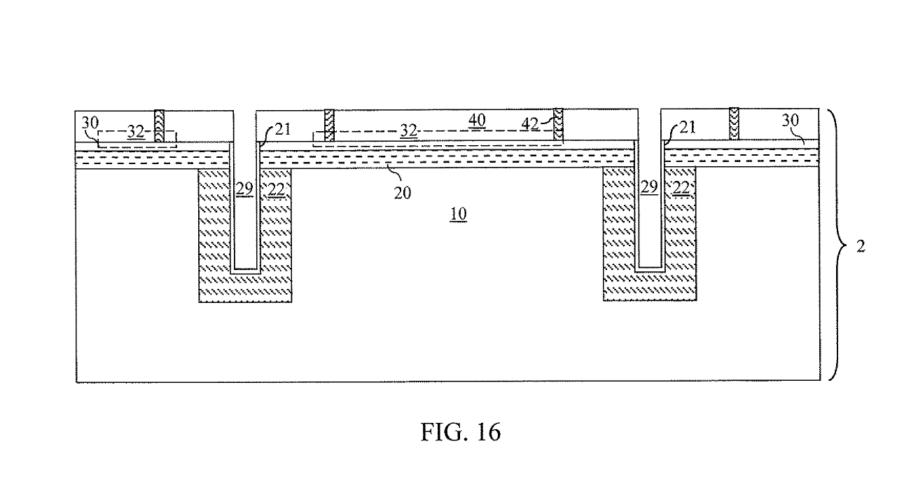

Referring to FIG. 16, a trench is formed by removing each temporary fill structure 28 and the portion of the first interconnect dielectric layer 40 located directly thereabove. Specifically, a mask layer (not shown) is lithographically patterned with the same pattern as the pattern of the at least one deep trench 27. The lithographically patterned mask layer includes an opening for each of the at least one deep trench 27 in FIG. 13. The exposed portions of the first interconnect dielectric layer 30 and all of the at least one temporary fill structure 28 are removed by an anisotropic etch. All inner sidewalls of the at least one TSV liner 21 is exposed after the anisotropic etch.

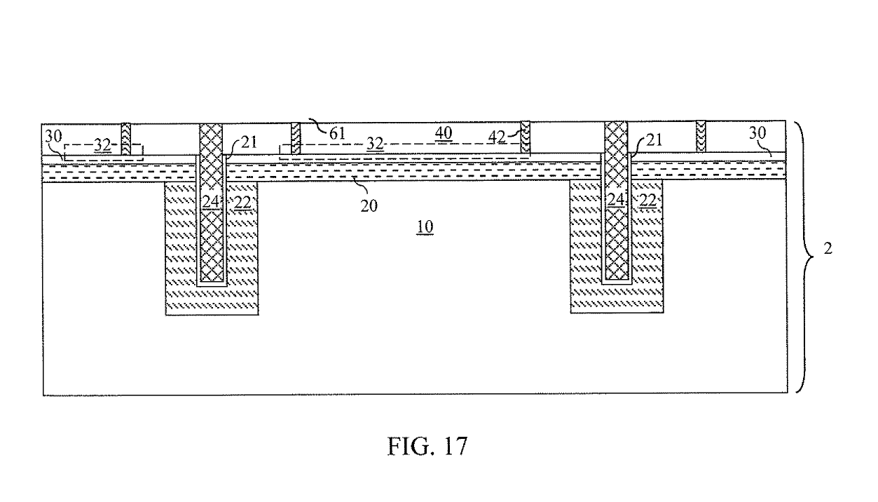

Referring to FIG. 17, a conductive fill material is deposited in each of the at least one trench 29 and planarized to remove excess materials above the topmost surface of the first interconnect dielectric layer 40. A first through-substrate via (TSV) structure 24 is formed within each TSV liner 21 by a remaining portion of the conductive material after planarization. The conductive material of the at least one first TSV structure 24 can be an elemental metal, an intermetallic alloy, a conductive metal nitride, a doped semiconductor material, or a combination thereof. The conductive material of the at least one first TSV structure 24 can be different from the material of the at least one doped buried plate 22. In one embodiment, each first TSV structure 24 is composed of W, Au, Ag, Cu, Ni, or an alloy thereof.

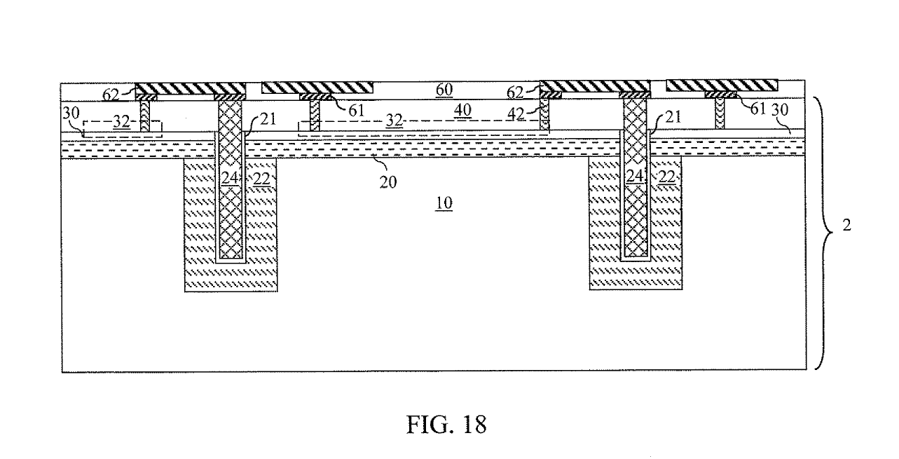

Referring to FIG. 18, a first front side dielectric layer 60 is formed on the first interconnect dielectric layer 40. The first front side dielectric layer 60 is composed of a dielectric material such as silicon oxide, silicon nitride, silicon oxynitride, or a combination thereof. First front side metal pads 62 are formed in the first front side dielectric layer 60 such that each of the first front side metal pads 62 is electrically connected to at least one of the at least one first TSV structure 24. Further, the first front side metal pads 62 can be electrically connected to at least one of the at least one first metal interconnect structure 42. The first front side metal pads 62 are embedded in the first front side dielectric layer 60. The thickness of the first front side dielectric layer 60 can be from 0.2 micron to 10 microns, although lesser and greater thicknesses can also be employed.

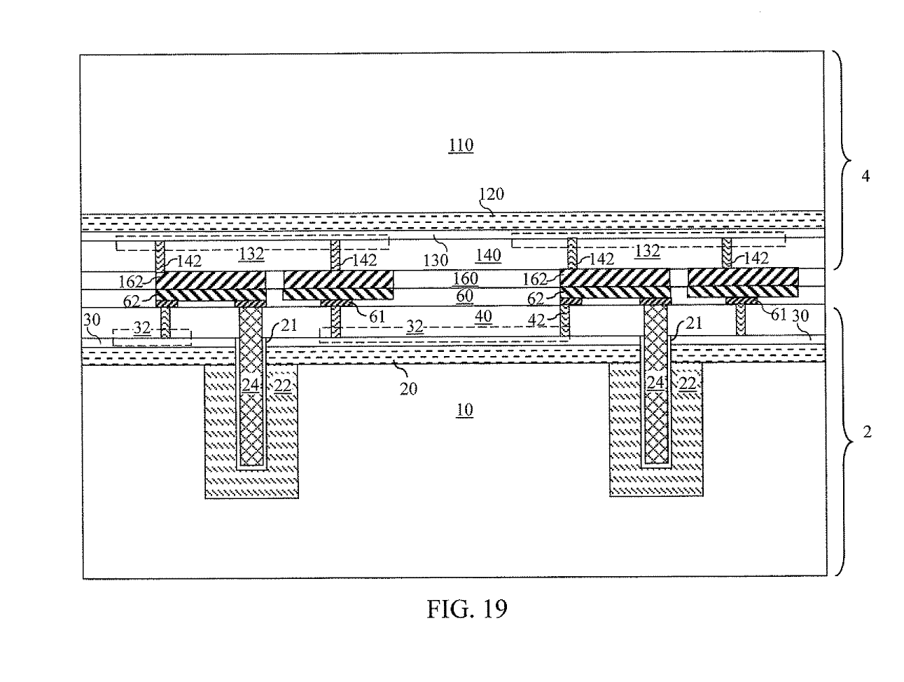

Referring to FIG. 19, a second substrate 4 is bonded to the first substrate 2 by methods known in the art. The first substrate 2 and the second substrate 4 collectively constitute a bonded substrate 8. The front side of the first substrate 2 is bonded to the front side or the back side of the second substrate 4. For example, if the front side of the first substrate 2 is bonded to the front side of the second substrate 4, second front side metal pads 162 that are embedded in a second front side dielectric layer 160 are formed on the second substrate 4. In this case, the second front side metal pads 162 in the second substrate 4 are bonded to the first front side metal pads 62 in the first substrate 2. The second substrate 4 can include the same components as the first embodiment.

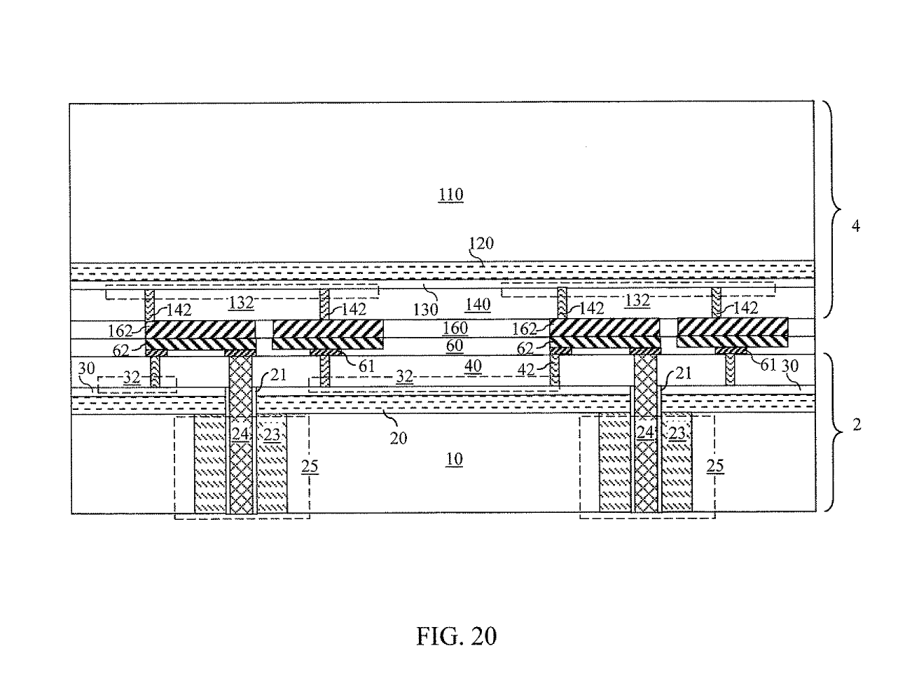

Referring to FIG. 20, the back side surface, i.e., the bottommost surface, of the first substrate 2 is recessed to expose horizontal end surfaces of each first TSV structure 24. The horizontal end surfaces of each first TSV structure 24 can be the bottommost surfaces of the corresponding first TSV structure 24 in FIG. 19. The recessing of the back side surface of the first substrate 2 can be effected, for example, by chemical mechanical planarization (CMP), mechanical grinding, dry etching, or a combination thereof. A bottom portion of each doped buried plate 22 is removed during the planarization. The remaining portion of each of the at least one TSV liner 21 become dielectric cylindrical structures that are topologically homeomorphic to a torus. Further, the remaining portion of each of the at least one doped buried plate 22 become conductive cylindrical structures that are topologically homeomorphic to a torus. Each remaining portion of a doped buried plate 22 is herein referred to as a second through-substrate via (TSV) structure 23, which extends from the interface between the first buried dielectric layer 20 and the bottommost surface of the first handle substrate 10. In one embodiment, the recessing of the back side surface of the first substrate 2 is performed such that the exposed end surfaces of each first TSV structure 24, each second TSV structure 23, and each TSV liner 21 are coplanar with the back side surface of the first handle substrate 10 at the end of the recessing.

After recessing the back side surface of the first substrate 2, each set of a first TSV structure 24, a TSV liner 21 surrounding the first TSV structure 24, and the second TSV structure 23 surrounding the TSV liner 21 collectively constitute a shielded through-substrate via (TSV) structure 25. Each first TSV structure 24 and each second TSV structure 23 are electrically isolated from the first substrate 2. Because a second TSV structure 23 laterally surrounds each first TSV structure 24, the second TSV structure 23 is configured to shield electrical signals within the first TSV structure 24 from external electromagnetic signals and to shield any other first TSV structure 24 from any electrical signals emanating from the first TSV structure 24 within the second TSV structure 23. The at least one first TSV structure 24 and the at least one second TSV structure 23 can include the same conductive material or different conductive materials. The conductive material of the at least one second TSV structure 23 is a doped semiconductor material. Typically, the conductive material of the at least one first TSV structure 24 is a metallic material. Each of the at least one first TSV structure 24 extends at least from the interface between the first top semiconductor layer 30 and the first interconnect dielectric layer 40 to the back side surface of the first substrate 2, which is the bottommost surface of the first handle substrate 10 after planarization. Each of the at least one second TSV structure 24 extends only through the first handle substrate 10.

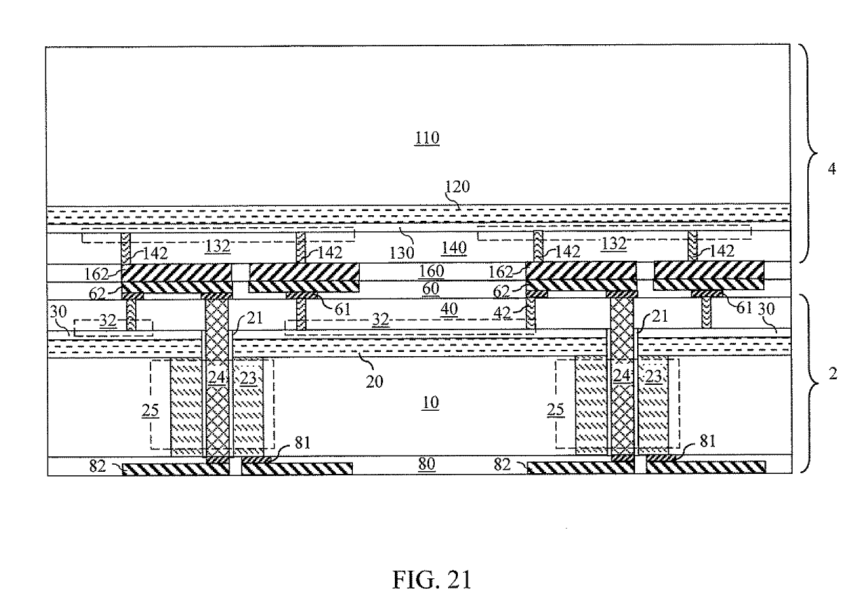

Referring to FIG. 21, a first back side dielectric layer 80 is formed on the back side of the first substrate 2 in the same manner as in the first embodiment.

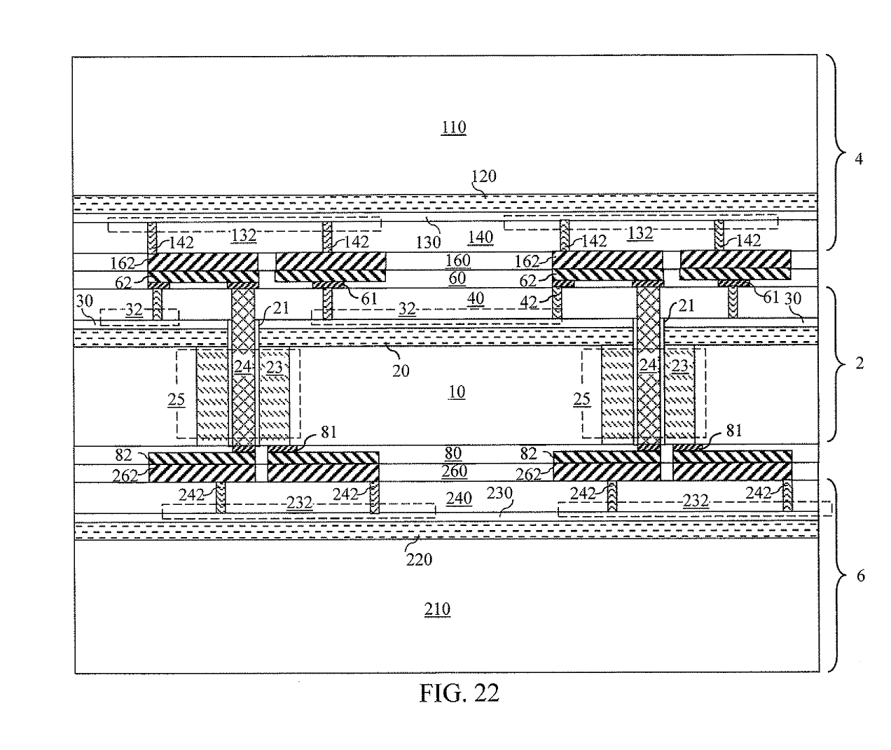

Referring to FIG. 22, a third substrate 6 is bonded to the first substrate 2 in the same manner as in the first embodiment. The third substrate 6 can have the same structure as in the first embodiment.

The third exemplary semiconductor structure includes a first substrate 2, which includes a semiconductor layer in the form of the first top semiconductor layer 30 and an interconnect dielectric layer in the form of the first interconnect dielectric layer 40. At least one first semiconductor device 32 is located at an interface between the semiconductor layer and the interconnect dielectric layer. At least one shielded through-substrate via (TSV) structure 25 is embedded in the first substrate 2. Each of the at least one shielded TSV structure 25 includes a first TSV structure 24 and a second TSV structure 23. The first TSV structure 24 is composed of a conductive material that can be selected from an elemental metal, an intermetallic alloy, a conductive metal nitride, a doped semiconductor material, and a combination thereof. For example, the at least one first TSV structure 24 can be composed of Au, Ag, Cu, W, Al, or a combination thereof. The second TSV structure 23 is composed of a doped semiconductor material. Each of the at least one first TSV structure 24 is electrically insulated from the first substrate 2, and extends at least from said interface between the first top semiconductor layer 30 and the first interconnect dielectric layer 40 to the back side surface of the first substrate 2. Each of the at least one second TSV structure 23 is electrically shorted to the first handle substrate 10, and extends only between the topmost surface and the bottommost surface of the first handle substrate 10.

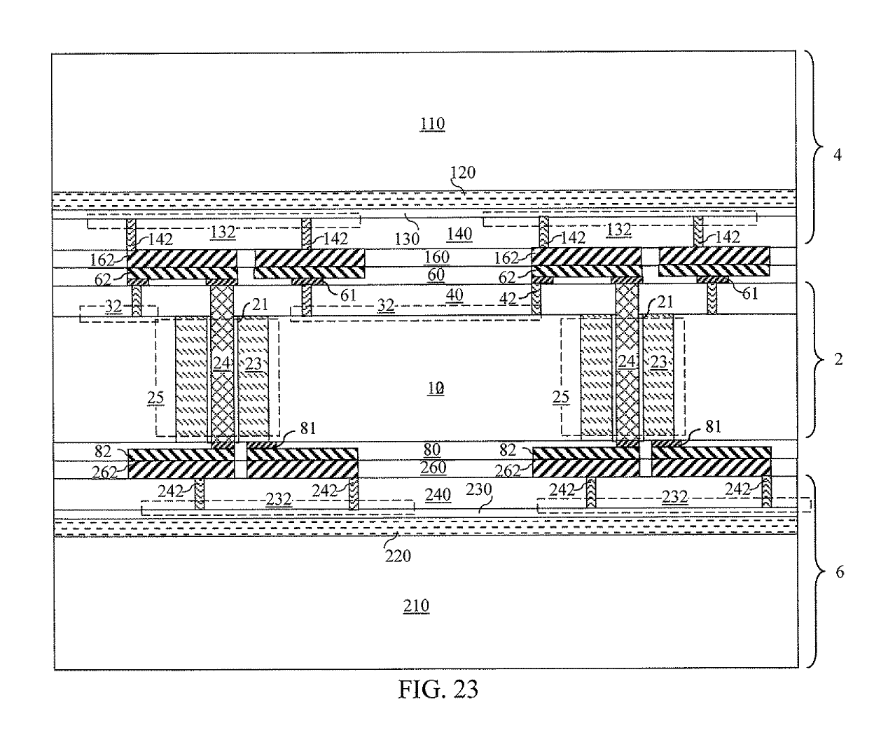

Referring to FIG. 23, a variation of the third exemplary semiconductor structure can be derived from the third exemplary semiconductor structure by employing a bulk substrate 12 for the first substrate 2 instead of an SOI substrate (10, 20, 30). The bulk substrate 12 can be composed of a single crystalline semiconductor material or a polycrystalline semiconductor material contiguously extending from the front side surface to the back side surface. The front side surface of the bulk substrate 12 is the interface between the bulk substrate 12 and the first interconnect dielectric layer 40. Each of the at least one second TSV structure 23 is electrically shorted to the first handle substrate 10, and extends only between the topmost surface and the bottommost surface of the bulk substrate 12.

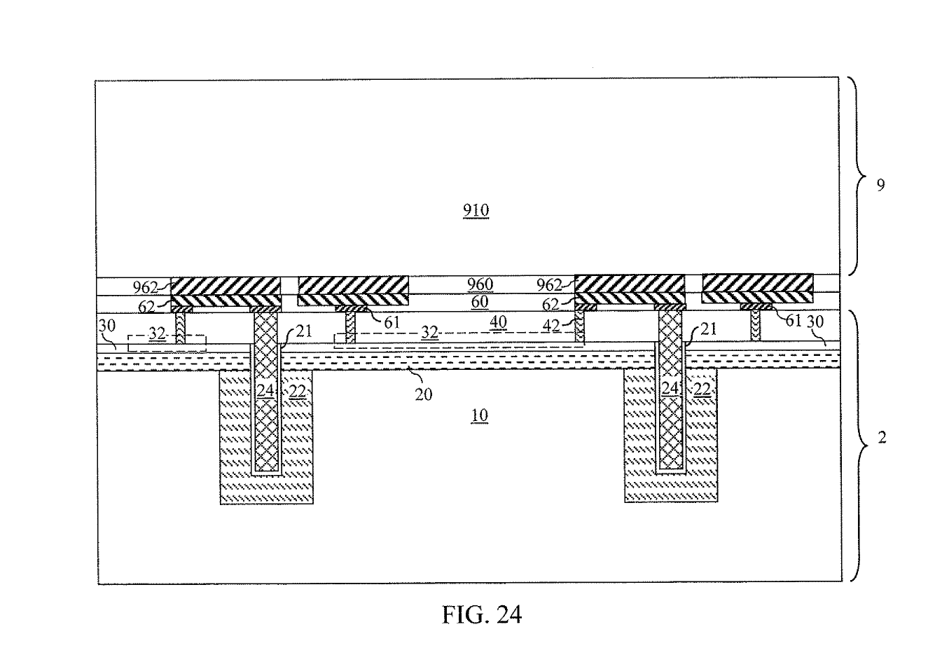

Referring to FIG. 24, a fourth exemplary semiconductor structure according to a fourth embodiment of the present invention is derived from the third exemplary structure of FIG. 18 by bonding a temporary substrate 9 to the first substrate 2. The temporary substrate 9 can be bonded to the first substrate 2 by methods known in the art. The first substrate 2 and the temporary substrate 9 collectively constitute a bonded substrate. The front side of the first substrate 2 is bonded to the temporary substrate 9. For example, terminal front side metal pads 962 that are embedded in a terminal front side dielectric layer 960 are formed on the front side of the temporary substrate 9. Subsequently, the terminal front side metal pads 962 in the temporary substrate 9 are bonded to the first front side metal pads 62 in the first substrate 2.

The temporary substrate 9 includes a temporary handle substrate 910, which can include a semiconductor material, a dielectric material, a conductive material, or a combination thereof. The thickness of the temporary substrate can be from 200 microns to 1,000 microns, although lesser and greater thicknesses can also be employed.

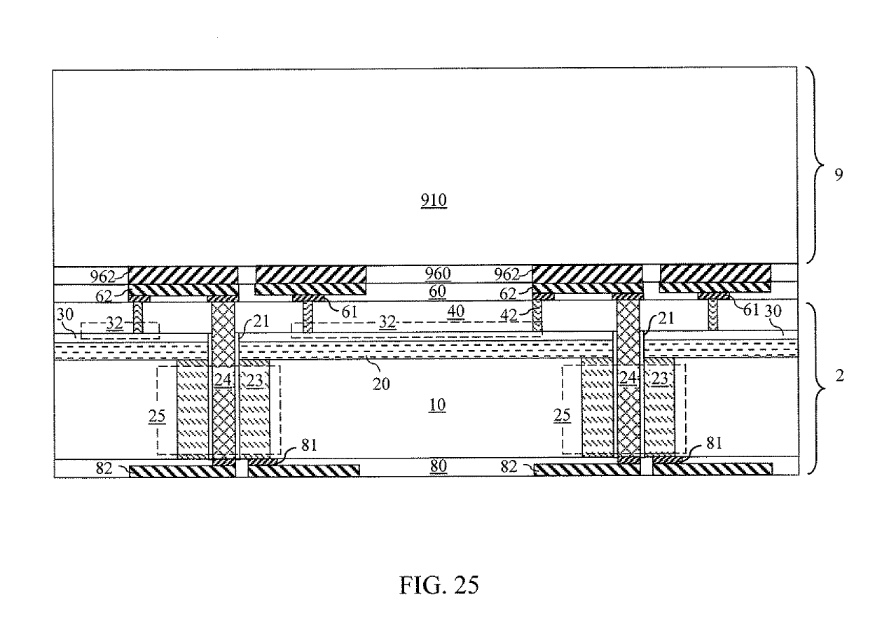

Referring to FIG. 25, processing steps of FIGS. 20 and 21 are performed in the same manner as in the third embodiment to recess the back side surface of the first substrate 2 and to form a first back side dielectric layer 80 and first back side metal pads 82 in the same manner as in the first and third embodiments.

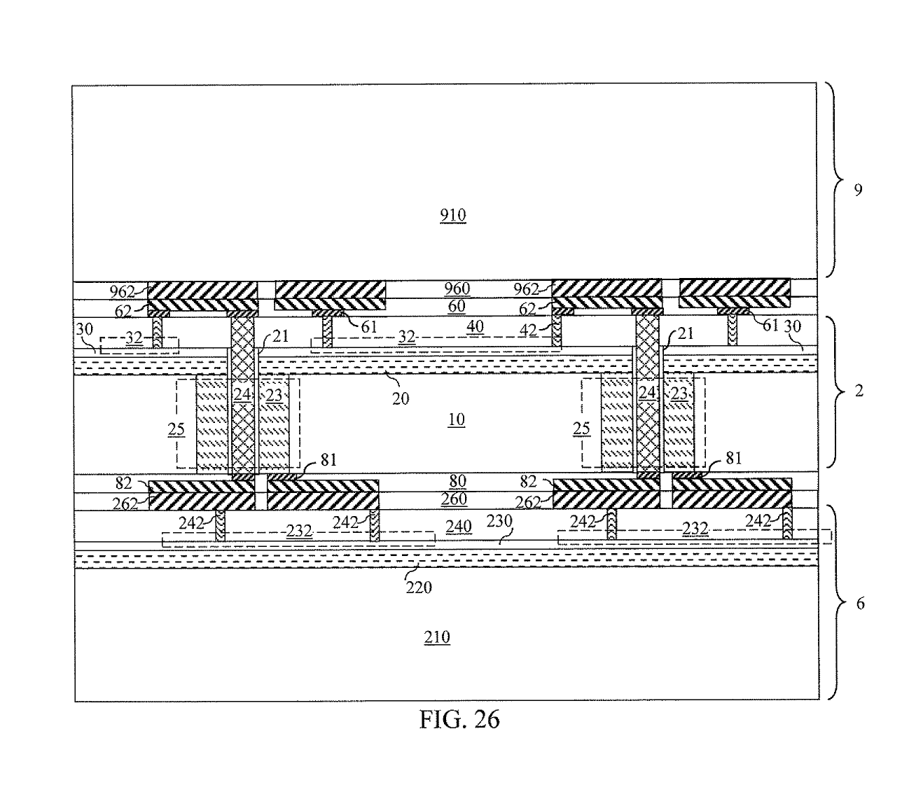

Referring to FIG. 26, processing steps of FIG. 22 are performed in the same manner as in the third embodiment to bond a third substrate 6. The third substrate 6 can be the same as in the second embodiment.

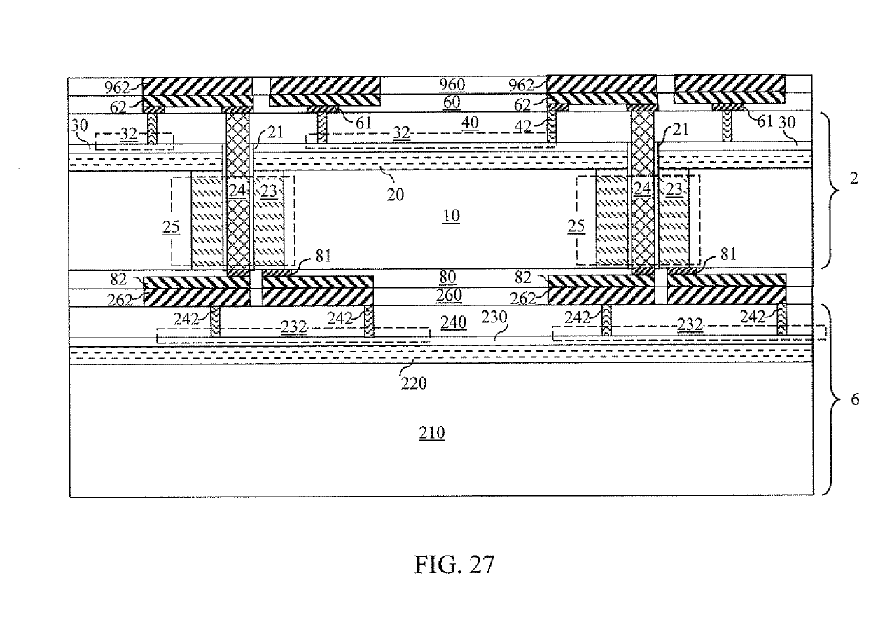

Referring to FIG. 27, the temporary substrate 9 is removed from the assembly of the substrates. The removal of the temporary substrate 9 can be effected, for example, by cleaving or by planarization of the temporary substrate 9. The at least one shielded TSV structure 25 in the first substrate 2 can have all of the features of the third exemplary structure in FIG. 25.

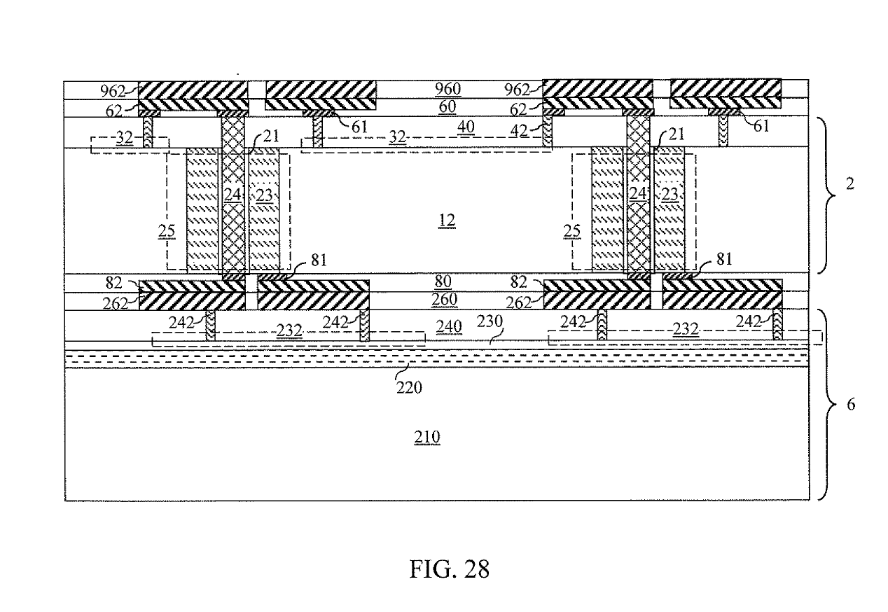

Referring to FIG. 28, a variation of the fourth exemplary semiconductor structure can be derived from the fourth exemplary semiconductor structure by employing a bulk substrate 12 for the first substrate 2 instead of an SOI substrate (10, 20, 30). The bulk substrate 12 can be composed of a single crystalline semiconductor material or a polycrystalline semiconductor material contiguously extending from the front side surface to the back side surface. The front side surface of the bulk substrate 12 is the interface between the bulk substrate 12 and the first interconnect dielectric layer 40. Each of the at least one second TSV structure 23 is electrically shorted to the first handle substrate 10, and extends only between the topmost surface and the bottommost surface of the bulk substrate 12.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims. For example, three or more chips could be stacked using this invention and/or through silicon vias could be used to connect the chips.

What is claimed is:

1. A semiconductor structure comprising:
a substrate including a semiconductor layer and an interconnect dielectric layer, wherein at least one semiconductor device is located at an interface between said semiconductor layer and said interconnect dielectric layer; and
at least one shielded through-substrate via (TSV) structure embedded in said substrate, each of said at least one shielded TSV structure comprising:
a first TSV structure comprising a first conductive material, electrically insulated from said substrate, and extending at least from said interface to a back side surface of said substrate; and
at least one second TSV structure comprising a second conductive material, extending from said back side surface of said substrate into said substrate, and configured to shield electrical signals within said first TSV structure from external electromagnetic signals.

2. The semiconductor structure of claim 1, wherein each of said at least one second TSV structure is electrically insulated from said substrate.

3. The semiconductor structure of claim 2, further comprising:
a first dielectric liner laterally surrounding said first TSV structure;
at least one second dielectric liner laterally surrounding each of said at least one second TSV structure, wherein said first dielectric liner and said at least one second dielectric liner comprise a same dielectric material.

4. The semiconductor structure of claim 2, wherein first conductive material and said second conductive material are a same conductive material selected from an elemental metal, an intermetallic alloy, a conductive metal nitride, a doped semiconductor material, and a combination thereof.

5. The semiconductor structure of claim 2, wherein said first TSV structure and said at least one second TSV structure have first end surfaces that are coplanar with a surface of said interconnect dielectric layer and second end surfaces that are coplanar with said back side surface of said substrate.

6. The semiconductor structure of claim 2, wherein said at least one second TSV structure is a contiguous unitary conductive structure that surrounds said first TSV structure and is spaced from said first TSV structure by a laterally enclosing structure having a same material composition as said substrate.

7. The semiconductor structure of claim 6, wherein said first TSV structure is laterally surrounded by structures that includes, from inside to outside, a first dielectric liner, said laterally enclosing structure, an inner second dielectric liner, said contiguous unitary conductive structure, an outer second dielectric liner, and said substrate.

8. The semiconductor structure of claim 2, wherein said at least one second TSV structure is not present at least within a range of azimuthal angles from a center of a horizontal cross-sectional area of said first TSV structure, wherein a magnitude of said range is less than 90 degrees.

9. The semiconductor structure of claim 8, wherein said at least one second TSV structure is a contiguous unitary conductive structure that is present at all azimuthal angles outside said range of azimuthal angles.

10. The semiconductor structure of claim 8, wherein said at least one second TSV structure is a plurality of second. TSV structures azimuthally spaced from each other by portions of said substrate and axially spaced from said first TSV structure by another portion of said substrate.

11. The semiconductor structure of claim 2, wherein said at least one shield TSV structure is a plurality of shield TSV structures including a plurality of first TSV structures and a plurality of second TSV structures, wherein said plurality of second TSV structures is located between each pair of first TSV structures among said plurality of first TSV structures to intercept all direct signal paths between said pair of first TSV structures.

12. The semiconductor structure of claim 1, wherein said at least one second TSV structure is a contiguous unitary conductive structure that surrounds said first TSV structure and is electrically shorted to said substrate.

13. The semiconductor structure of claim 12, wherein said substrate includes a semiconductor layer, and said at least one second structure is a doped semiconductor portion located in said semiconductor layer.

14. The semiconductor structure of claim 13, wherein said substrate is a bulk semiconductor substrate, said at least one second structure extends from a back side surface of said bulk semiconductor substrate to a front side surface of said bulk semiconductor substrate, and said at least one semiconductor device is located on said front side surface of said bulk semiconductor substrate.

15. The semiconductor structure of claim 13, wherein said substrate is a semiconductor-on-insulator (SOT) substrate including a stack of a semiconductor handle substrate, a buried insulator layer, and a top semiconductor layer, said at least one second structure extends from a back side surface of said semiconductor handle substrate to an interface between said semiconductor handle substrate and said buried insulator layer, and said at least one semiconductor device is located on a front side surface of said top semiconductor layer.

16. The semiconductor structure of claim 12, further comprising a dielectric liner contacting an entirety of sidewalls of said first TSV structure and an entirety of inner sidewalls of said contiguous unitary conductive structure.

17. The semiconductor structure of claim 12, wherein said first conductive material is different from said second conductive material, and is selected from an elemental metal, an intermetallic alloy, a conductive metal nitride, a doped semiconductor material, and a combination thereof.

18. The semiconductor structure of claim 12, wherein a portion of said first TSV structure is laterally surrounded by said interconnect dielectric layer.

19. A method of forming a semiconductor structure comprising:
forming a plurality of trenches extending from a front side surface of a substrate into said substrate;
forming a dielectric liner in each of said plurality of trenches;
filling said plurality of trenches with a conductive material; and
recessing a back side surface of said substrate, wherein remaining portions of said conductive material in said plurality of trenches constitute at least one shielded through-substrate via (TSV) structure embedded in said substrate, and wherein each of said at least one shielded TSV structure includes a first TSV structure and at least one second TSV structure, said first TSV structure and said at least one second TSV structure are electrically isolated from said substrate, and said at least one second TSV structure is configured to shield electrical signals within said first TSV structure from external electromagnetic signals.

20. The method of claim 19, wherein end surfaces of said first TSV structure and said at least one second TSV structure are coplanar with said back side surface after said recessing.

21. The method of claim 19, wherein said at least one second TSV structure is formed as a contiguous unitary conductive structure that surrounds said first TSV structure and is spaced from said first TSV structure by a laterally enclosing structure having a same material composition as said substrate.

22. The method of claim 19, wherein said at least one shield TSV structure is formed as a plurality of shield TSV structures including a plurality of first TSV structures and a plurality of second TSV structures, wherein said plurality of second TSV structures is located between each pair of first TSV structures among said plurality of first TSV structures to intercept all direct signal paths between said pair of first TSV structures.

23. A method of forming a semiconductor structure comprising:
forming a trench extending from a front side surface of a substrate into said substrate;
doping a semiconductor material portion around said trench to form a doped semiconductor material portion by introducing dopants through sidewalls of said trench into said substrate;
forming a dielectric liner on sidewalls of said doped semiconductor material portion;
filling said trench with a conductive material; and
recessing a back side surface of said substrate, wherein a remaining portion of said conductive material in said trench constitutes a first through-substrate via (TSV) structure and a remaining portion of said doped semiconductor material portion constitutes a second TSV structure, and said first TSV structure and said second TSV structure have end surfaces that are coplanar with said back side surface after said recessing.

24. The method of claim 23, wherein said substrate is a bulk semiconductor substrate comprising a contiguous semiconductor material extending from said front side surface to said back side surface.

25. The method of claim 24, wherein said substrate is a semiconductor-on-insulator (SOI) substrate comprising a stack of a semiconductor handle substrate, a buried insulator layer, and a top semiconductor layer, and said second TSV structure extends from said back side surface to an interface between said semiconductor handle substrate and said buried insulator layer.
